(19) United States
(12) Patent Application Publication
(10) Pub. No.: US 2019/0127848 A1
(43) Pub. Date: May 2, 2019

(54) Processing Method, Method of Manufacturing Semiconductor Device and Non-transitory Computer-readable Recording Medium

(71) Applicant: Kokusai Electric Corporation, Tokyo (JP)

(72) Inventors: Masaya NAGATO, Toyama (JP); Shin SONE, Toyama (JP); Kenji KAMEDA, Toyama (JP); Masayuki TSUNEDA, Toyama (JP); Masato TERASAKI, Toyama (JP)

(21) Appl. No.: 16/215,303

(22) Filed: Dec. 10, 2018

Related U.S. Application Data
(63) Continuation of application No. PCT/JP2017/010219, filed on Mar. 14, 2017.

(30) Foreign Application Priority Data
Jun. 10, 2016 (JP) 2016-116528

(51) Int. Cl. C23C 16/44; H01L 21/02

(52) U.S. Cl. CPC C23C 16/4405; H01L 21/0228; H01L 21/02164; C23C 16/4408

(57) ABSTRACT

In the disclosure, a processing method is provided. The method includes: (a) processing a substrate accommodated in a substrate holding region of a substrate retainer in a process chamber at a first temperature, the substrate retainer including a heat insulating region on one end thereof and the substrate holding region on the other end thereof; (b) supplying a cleaning gas to the heat insulating region at a second temperature variable within a temperature range lower than the first temperature and higher than a room temperature after unloading the substrate accommodated in the substrate retainer; and (c) supplying the cleaning gas to the substrate holding region at a third temperature variable within another temperature range lower than the second temperature after unloading the substrate accommodated in the substrate retainer.

### CROSS REFERENCE TO RELATED APPLICATIONS

This application is a continuation of International Application No. PCT/JP2017/010219, filed on Mar. 14, 2017, which claims priority under 35 U.S.C. § 119 to Application No. JP 2016-116528 filed on Jun. 10, 2016, the entire contents of which are hereby incorporated by reference.

### TECHNICAL FIELD

The present disclosure relates to a processing method, a method of manufacturing a semiconductor device and a non-transitory computer-readable recording medium.

### BACKGROUND

When a film-forming process is performed for forming a deposition film on a substrate in a process chamber of a substrate processing apparatus, deposits (that is, deposited materials) such as a film and by-products (hereinafter, also referred to as “reaction by-products”) are deposited not only on the substrate but also in other regions in the process chamber. As a method of removing the deposits, a cleaning gas is supplied into the process chamber to remove the deposits. For example, hydrogen fluoride (HF) gas may be used as the cleaning gas.

However, the etching rate may be different between one end of the process chamber and the other end of the process chamber. Therefore, the deposits such as the reaction by-products are liable to remain in locations wherefrom it is difficult to remove the deposits due to the variation in the etching rate. In order to remove the deposits such as the reaction by-products remaining in such locations as above, it is necessary to supply the cleaning gas for a longer time. In addition, if the cleaning by the cleaning gas is not sufficient to remove the deposits, the deposits must be removed manually by, for example, wiping the deposits. As a result, the time required for cleaning the deposits is prolonged.

### SUMMARY

Described herein is a technique capable of shortening the time required for performing the cleaning process while suppressing the variation of the etching rate depending on the location in the cleaning region.

According to one aspect of the technique described herein, there is provided a processing method including: (a) processing a substrate accommodated in a substrate holding region of a substrate retainer in a process chamber at a first temperature, the substrate retainer including a heat insulating region on one end thereof and the substrate holding region on the other end thereof; (b) supplying a cleaning gas to the heat insulating region at a second temperature variable within a temperature range lower than the first temperature and higher than a room temperature after unloading the substrate accommodated in the substrate retainer; and (c) supplying the cleaning gas to the substrate holding region at a third temperature variable within another temperature range lower than the second temperature after unloading the substrate accommodated in the substrate retainer.

### BRIEF DESCRIPTION OF THE DRAWINGS

FIG. 1 schematically illustrates a vertical cross-section of a vertical type process furnace of a substrate processing apparatus preferably used in one or more embodiments described herein.

FIG. 2 is a partial enlarged view schematically illustrating the cross-sectional structure in the vicinity of a nozzle 40b of the vertical type process furnace of the substrate processing apparatus preferably used in the embodiments.

FIG. 3 schematically illustrates a cross-section taken along the line A-A of the vertical type process furnace of the substrate processing apparatus shown in FIG. 1.

FIG. 4 is a block diagram schematically illustrating a configuration of a controller and components controlled by the controller of the substrate processing apparatus preferably used in the embodiments.

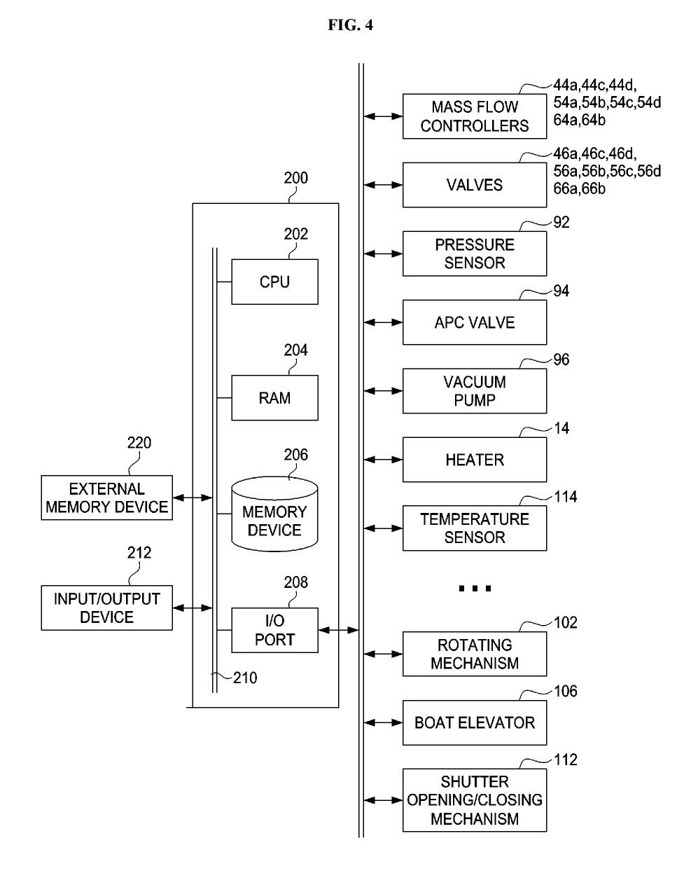

FIG. 5 is a flowchart schematically illustrating a film-forming process and a cleaning process according to the embodiments.

FIG. 6 is a timing diagram schematically illustrating a gas supply of the film-forming process according to the embodiments.

FIG. 7 is a timing diagram of temperature during the cleaning process according to the embodiments.

FIG. 8 is a timing diagram of pressure during the cleaning process according to the embodiments when a cleaning gas is supplied.

FIG. 9 schematically illustrates experimental results obtained by performing the cleaning process according to the embodiments.

FIG. 10A is a diagram schematically illustrating a heat insulating region and a wafer holding region of the substrate processing apparatus preferably used in the embodiments.

FIG. 10B is another diagram schematically illustrating the heat insulating region and the wafer holding region of the substrate processing apparatus preferably used in the embodiments.

FIG. 11 schematically illustrates the relationship between an inner temperature of the process chamber 22 and the cooling time according to the embodiments.

FIG. 12A is a timing diagram of temperature during a cleaning process according to a comparative example.

FIG. 12B is a timing diagram of pressure during the cleaning process when the cleaning gas is supplied according to the comparative example.

FIG. 13A schematically illustrates experimental results obtained by performing the cleaning process according to the embodiments and the cleaning process according to the comparative example.

FIG. 13B schematically illustrates experimental results obtained by performing the cleaning process according to the embodiments and the cleaning process according to the comparative example.

FIG. 14 is a timing diagram of temperature during the cleaning process according to a modified example of the embodiments.

### DETAILED DESCRIPTION

### (1) Configuration of Substrate Processing Apparatus

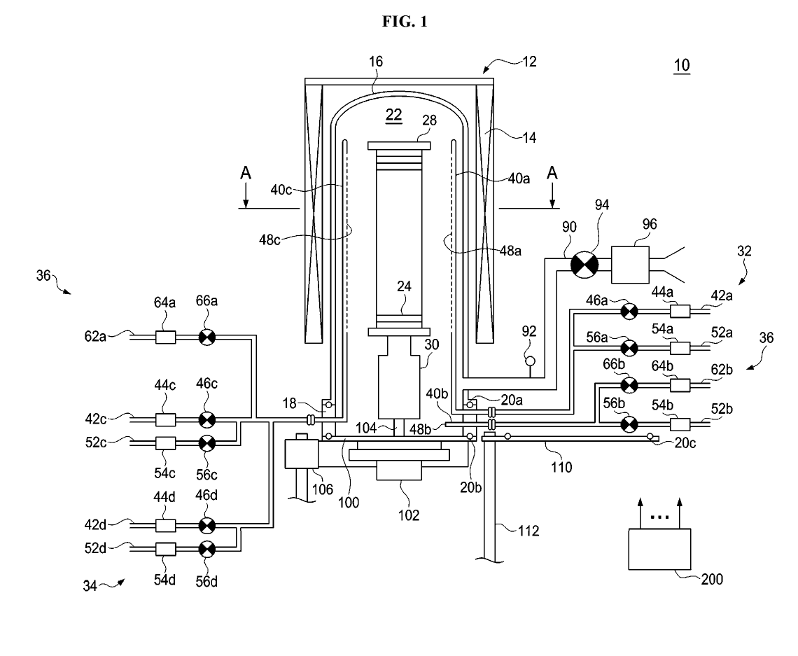

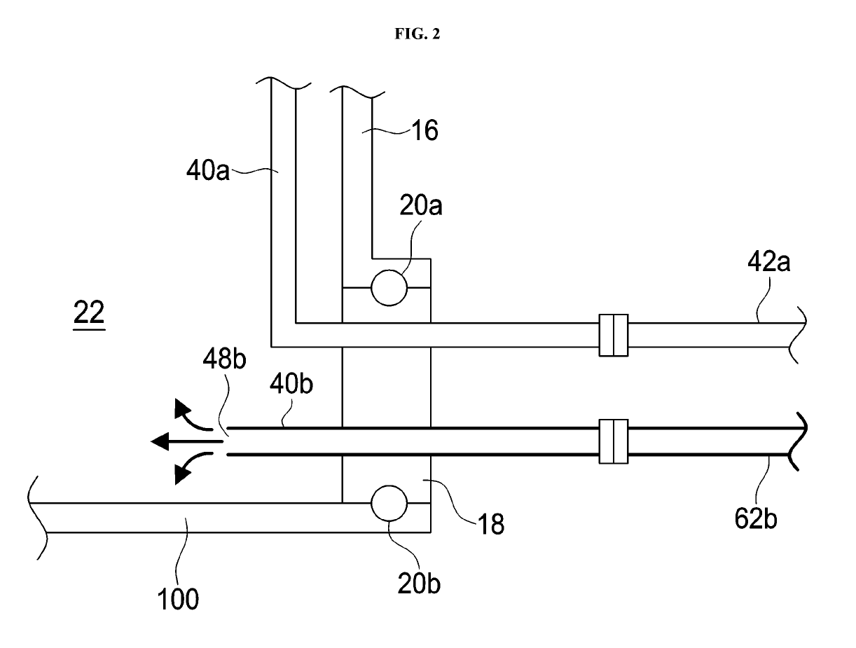

Hereinafter, one or more embodiments according to the technique will be described with reference to FIGS. 1 through 3. A process furnace 12 includes a heater 14 serving as a heating apparatus (heating mechanism). The heater 14 is cylindrical, and vertically installed while being supported by a heater base (not shown) serving as a support plate. In addition, the heater 14 also functions as an activation mechanism (excitation mechanism) for activating (exciting) the gas by heat.

A reaction tube 16 is provided in the heater 14 so as to be concentric with the heater 14. The reaction tube 16 is cylindrical with a closed upper end and an open lower end. The reaction tube 16 is made of a heat resistant material such as quartz (SiO₂) and silicon carbide (SiC).

An inlet flange (hereinafter, also referred to as an “inlet” or a “manifold”) 18 is provided under the reaction tube 16 so as to be concentric with the reaction tube 16. The inlet 18 is cylindrical with open upper and lower ends. The inlet 18 is made of a metal such as stainless steel (SUS). An upper end portion of the inlet 18 is engaged with the lower end of the reaction tube 16 so as to support the reaction tube 16.

An O-ring 20a serving as a sealing part is provided between the inlet 18 and the reaction tube 16. The reaction tube 16 is vertically installed by the inlet 18 being supported by the heater base.

A process vessel (reaction vessel) is constituted mainly by the reaction tube 16 and the inlet 18. A process chamber 22 is provided in a hollow cylindrical portion of the process vessel. An opening portion for loading wafers 24 serving as substrates into the process chamber 22 and for unloading the wafers 24 out of the process chamber 22 is provided under the process chamber 22. The process chamber 22 is configured to accommodate the vertically arranged wafers 24 in a horizontal orientation in a multistage manner by a boat 28 serving as a substrate retainer capable of accommodating the wafers 24. Hereinafter, the wafers 24 may also be referred to as the substrates 24.

The boat 28 aligns the substrates 24 in the vertical direction and supports the substrates 24, while the substrates 24 are horizontally oriented with their centers aligned with each other. The boat 28 is made of a heat resistant material such as quartz and SiC. A heat insulating part 30 is provided under the boat 28. The heat insulating part 30 may be constituted by a plurality of heat insulating plates (not shown) made of a heat resistant material such as quartz and SiC and a heat insulating plate holder for supporting the plurality of heat insulating plates in a horizontal orientation in a multistage manner.

The process furnace 12 is provided with a first gas supply system (hereinafter, also referred to as a “source gas supply system”) 32, a second gas supply system (hereinafter, also referred to as a “reactive gas supply system”) 34 and a third gas supply system (hereinafter, also referred to as a “cleaning gas supply system”) 36. The first gas supply system 32 is configured to supply a first gas (for example, a source gas) for processing the substrates 24 into the process chamber 22. The second gas supply system 34 is configured to supply a second gas (for example, a reactive gas) for processing the substrates 24 into the process chamber 22. The third gas supply system 36 is configured to supply a third gas (for example, a cleaning gas) for cleaning an inside of the process chamber 22 into the process chamber 22.

The process furnace 12 is provided with nozzles 40a, 40b and 40c configured to supply various gases into the process chamber 22. The nozzles 40a, 40b and 40c are provided in the process chamber 22 through a sidewall of the inlet 18. The nozzles 40a, 40b and 40c are made of a heat resistant material such as quartz and SiC. A gas supply pipe 42a and an inert gas supply pipe 52a are connected to the nozzle 40a. A gas supply pipe 42b and an inert gas supply pipe 52b are connected to the nozzle 40b. A gas supply pipe 42c, an inert gas supply pipe 52c, a cleaning gas supply pipe 62a, a gas supply pipe 42d and an inert gas supply pipe 52d are connected to the nozzle 40c.

A mass flow controller (MFC) 44a serving as a flow rate controller (flow rate control mechanism) and a valve 46a serving as an opening/closing valve are sequentially provided at the gas supply pipe 42a from the upstream side toward the downstream side of the gas supply pipe 42a. The inert gas supply pipe 52a is connected to the gas supply pipe 42a at the downstream side of the valve 46a. The nozzle 40a is connected to a front end of the gas supply pipe 42a. An MFC 54a and a valve 56a are sequentially provided at the inert gas supply pipe 52a from the upstream side toward the downstream side of the inert gas supply pipe 52a.

The nozzle 40a is provided in an annular space between an inner wall of the reaction tube 16 and the substrates 24 accommodated in the process chamber 22, and extends from the inlet 18 to an inside of the reaction tube 16 along a stacking direction of the substrates 24. The nozzle 40a is provided in a region that horizontally surrounds a wafer holding region (hereinafter, also referred to as a “substrate holding region”) at one side of the wafer holding region where the substrates 24 are accommodated along the wafer holding region.

A plurality of gas supply holes 48a is provided at a side surface of the nozzle 40a. The plurality of gas supply holes 48a is open toward the center of the reaction tube 16. The plurality of gas supply holes 48a is configured to supply the gas such as a source gas toward the substrates 24 accommodated in the process chamber 22. The plurality of gas supply holes 48a is provided from a lower portion of the wafer holding region in the reaction tube 16 to an upper portion thereof.

The first gas supply system 32 is constituted mainly by the gas supply pipe 42a, the MFC 44a and the valve 46a. A first inert gas supply system is constituted mainly by the inert gas supply pipe 52a, the MFC 54a and the valve 56a.

The source gas containing a predetermined element and a halogen element is supplied through the gas supply pipe 42a. For example, a chlorosilane-based source gas serving as the source gas containing silicon (Si) as the predetermined element and chlorine (Cl) as the halogen element is supplied into the process chamber 22 via the MFC 44a and the valve 46a provided at the gas supply pipe 42a and the nozzle 40a. For example, hexachlorodisilane (Si₂Cl₆, abbreviated as HCDS) gas may be used as the chlorosilane-based source gas.

The source gas refers to a source which remains in gaseous state under normal temperature and pressure or a gas obtained by vaporizing a liquid source under normal temperature and pressure. The chlorosilane-based source refers to a silane-based source containing chloro group as a halogen group, that is, a source containing at least silicon (Si) and chlorine (Cl).

An MFC 44c and a valve 46c are sequentially provided at the gas supply pipe 42c from the upstream side toward the downstream side of the gas supply pipe 42c. The inert gas supply pipe 52c is connected to the gas supply pipe 42c at the downstream side of the valve 46c. An MFC 54c and a valve 56c are sequentially provided at the inert gas supply pipe 52c from the upstream side toward the downstream side of the inert gas supply pipe 52c.

The nozzle 40c is provided in the annular space and extends from a lower portion of the reaction tube 16 to an upper portion thereof. The nozzle 40c is provided in the region that horizontally surrounds the wafer holding region at one side of the wafer holding region where the substrates 24 are accommodated along the wafer holding region.

A plurality of gas supply holes 48c is provided at a side surface of the nozzle 40c. The plurality of gas supply holes 48c is open toward the center of the reaction tube 16. The plurality of gas supply holes 48c is configured to supply the gas such as the reactive gas toward the substrates 24 accommodated in the process chamber 22. The plurality of gas supply holes 48c is provided from the lower portion of the wafer holding region in the reaction tube 16 to the upper portion thereof.

The gas supply pipe 42d is connected to the gas supply pipe 42c at the downstream sides of the valve 46c provided at the gas supply pipe 42c and the valve 56c provided at the inert gas supply pipe 52c. An MFC 44d and a valve 46d are sequentially provided at the gas supply pipe 42d from the upstream side toward the downstream side of the gas supply pipe 42d. The inert gas supply pipe 52d is connected to the gas supply pipe 42d at the downstream side of the valve 46d. An MFC 54d and a valve 56d are sequentially provided at the inert gas supply pipe 52d from the upstream side toward the downstream side of the inert gas supply pipe 52d.

The second gas supply system 34 is constituted mainly by the nozzle 40c, the gas supply pipes 42c and 42d, the MFCs 44c and 44d and the valves 46c and 46d. A second inert gas supply system is constituted mainly by the inert gas supply pipes 52c and 52d, the MFCs 54c and 54d and the valves 56c and 56d.

The reactive gas such as an oxygen (O)-containing gas is supplied through the gas supply pipe 42c. The oxygen-containing gas serves as an oxidation gas. For example, an oxygen gas (O₂ gas) serving as the oxygen-containing gas is supplied into the process chamber 22 via the MFC 44c and the valve 46c provided at the gas supply pipe 42c and the nozzle 40c. When the oxygen gas is supplied into the process chamber 22, an inert gas may be supplied into the gas supply pipe 42c via the MFC 54c and the valve 56c provided at the inert gas supply pipe 52c.

The reactive gas such as a hydrogen (H)-containing gas is supplied through the gas supply pipe 42d. The hydrogen-containing gas serves as a reducing gas. For example, a hydrogen gas (H2 gas) serving as the hydrogen-containing gas is supplied into the process chamber 22 via the MFC 44d and the valve 46d provided at the gas supply pipe 42d and the nozzle 40c. When the hydrogen gas is supplied into the process chamber 22, the inert gas may be supplied into the gas supply pipe 42d via the MFC 54d and the valve 56d provided at the inert gas supply pipe 52d.

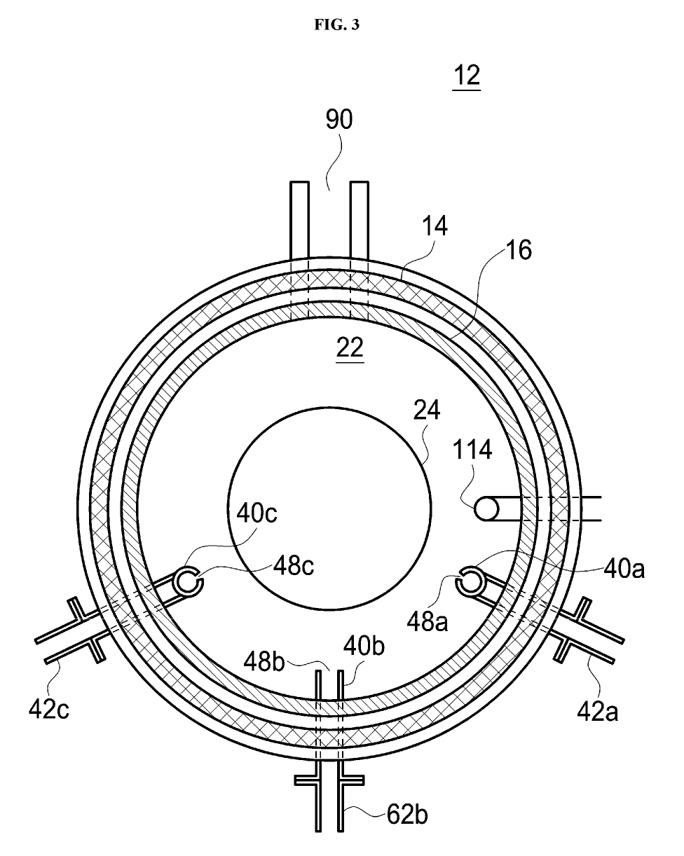

The cleaning gas supply pipe 62a is connected to the gas supply pipe 42c. An MFC 64a and a valve 66a are sequentially provided at the cleaning gas supply pipe 62a from the upstream side toward the downstream side of the cleaning gas supply pipe 62a. An MFC 64b and a valve 66b are sequentially provided at the cleaning gas supply pipe 62b from the upstream side toward the downstream side of the cleaning gas supply pipe 62b. The inert gas supply pipe 52b is connected to the cleaning gas supply pipe 62b at the downstream side of the valve 66b. An MFC 54b and a valve 56b are sequentially provided at the inert gas supply pipe 52b from the upstream side toward the downstream side of the inert gas supply pipe 52b. Referring to FIG. 3, the nozzle 40b is disposed so as to face an exhaust pipe 90 described later via the boat 28 accommodated in the process chamber 22 between the nozzle 40b and the exhaust pipe 90, that is, via the substrates 24. In FIG. 1, for the convenience of illustration, the positions of the components such as the nozzles 40a, 40b and 40c and the exhaust pipe 90 are illustrated slightly different from their actual positions.

A gas supply hole 48b configured to supply the gas such as the cleaning gas is provided at a front end of the nozzle 40b. The gas supply hole 48b is open in the horizontal direction. More specifically, the gas supply hole 48b is open in the direction from an inner wall side of the inlet 18 toward an inside of the inlet 18. The nozzle 40b is configured to supply the gas such as the cleaning gas into the process chamber 22 such that the gas is supplied at a position closer to the inlet 18 than the nozzle 40c in a heat insulating region.

A first cleaning gas supply system is constituted mainly by the nozzle 40b, the cleaning gas supply pipe 62b, the MFC 64b and the valve 66b. A second cleaning gas supply system is constituted mainly by the nozzle 40c, the cleaning gas supply pipe 62a, the MFC 64a and the valve 66a. A third inert gas supply system is constituted mainly by the inert gas supply pipe 52b, the MFC 54b and the valve 56b. The third gas supply system 36 is constituted by the first cleaning gas supply system and the second cleaning gas supply system.

The cleaning gas such as a fluorine (F)-containing gas is supplied through the cleaning gas supply pipe 62a. For example, hydrogen fluoride (HF) gas serving as the fluorine-containing gas is supplied into the process chamber 22 via the MFC 64a and the valve 66a provided at the cleaning gas supply pipe 62a, the gas supply pipe 42 c and the nozzle 40c. Specifically, the hydrogen fluoride gas is supplied mainly to the surfaces of the components (for example, the inner wall of the reaction tube 16 in the wafer holding region and the boat 28 accommodated in the process chamber 22). When the cleaning gas is supplied into the process chamber 22 through the cleaning gas supply pipe 62a, the inert gas may be supplied into the process chamber 22 through the inert gas supply pipes 52c and 52d. Specifically, the inert gas may be supplied into the process chamber 22 via the MFCs 54c and 54d and the valves 56c and 56d provided at the inert gas supply pipes 52c and 52d, the gas supply pipe 42c and the nozzle 40c. Compared to other kinds of cleaning gas, the hydrogen fluoride gas can remove oxide-based deposits at a lower temperature, for example, a temperature lower than 100° C.

Similarly, the cleaning gas such as the fluorine-containing gas is supplied through the cleaning gas supply pipe 62b. For example, the hydrogen fluoride (HF) gas serving as the fluorine-containing gas is supplied into the process chamber 22 via the MFC 64b and the valve 66b provided at the cleaning gas supply pipe 62b and the nozzle 40b. Specifically, the hydrogen fluoride gas is supplied mainly to the surfaces of the components (for example, the inner wall of the reaction tube 16, the inner wall side of the inlet 18 in the heat insulating region and the boat 28 accommodated in the process chamber 22). When the cleaning gas is supplied into the process chamber 22 through the cleaning gas supply pipe 62b, the inert gas may be supplied into the cleaning gas supply pipe 62b through the inert gas supply pipe 52b. Specifically, the inert gas may be supplied into the cleaning gas supply pipe 62b via the MFC 54b and the valve 56b provided at the inert gas supply pipe 52b.

The exhaust pipe 90 configured to exhaust an inner atmosphere of the process chamber 22 is provided at the reaction tube 16. A vacuum pump 96 serving as a vacuum exhauster is connected to the exhaust pipe 90 through a pressure sensor 92 and an APC (Automatic Pressure Controller) valve 94. The pressure sensor 92 serves as a pressure detector (pressure detection mechanism) to detect an inner pressure of the process chamber 22, and the APC valve 94 serves as a pressure controller (pressure adjusting mechanism). With the vacuum pump 96 in operation, the APC valve 94 may be opened/closed to vacuum-exhaust the process chamber 22 or stop the vacuum exhaust.

An exhaust system is constituted mainly by the exhaust pipe 90, the pressure sensor 92 and the APC valve 94. The exhaust system may further include the vacuum pump 96. With the vacuum pump 96 in operation, an opening degree of the APC valve 94 may be adjusted based on the pressure detected by the pressure sensor 92, in order to control the inner pressure of the process chamber 22 to a predetermined pressure (vacuum degree). Similar to the components such as the nozzle 40a and the nozzle 40b provided at the inlet 18, the exhaust pipe 90 may be provided at the inlet 18 instead of the reaction tube 16.

A seal cap 100 serving as a first furnace opening cover capable of airtightly sealing a lower end opening of the inlet 18, is provided under the inlet 18. The seal cap 100 is in contact with the lower end of the inlet 18 from thereunder. The seal cap 100 is made of a metal such as stainless steel, and is disk-shaped. An O-ring 20b serving as a sealing part is provided on an upper surface of the seal cap 100 so as to be in contact with the lower end of the inlet 18.

A rotating mechanism 102 configured to rotate the boat 28 is provided under the seal cap 100 opposite to the process chamber 22. A rotating shaft 104 of the rotating mechanism 102 is connected to the boat 28 through the seal cap 100. The rotating shaft 104 is made of a metal such as stainless steel. As the rotating mechanism 102 rotates the boat 28, the substrates 24 supported by the boat 28 are rotated.

A boat elevator 106 serving as an elevating mechanism is provided at the outside the reaction tube 16 vertically. The seal cap 100 may be moved upward/downward in the vertical direction by the boat elevator 106. When the seal cap 100 is moved upward/downward by the boat elevator 106, the boat 28 placed on the seal cap 100 may be loaded into the process chamber 22 or unloaded out of the process chamber 22. The boat elevator 106 serves as a transfer device (transfer mechanism) that loads the boat 28, that is, the substrates 24 accommodated in the boat 28 into the process chamber 22 or unloads the boat 28, that is, the substrates 24 accommodated in the boat 28 out of the process chamber 22.

A shutter 110 serving as a second furnace opening cover capable of airtightly sealing the lower end opening of the inlet 18, is provided under the inlet 18. The shutter 110 is made of a metal such as stainless steel, and is disk-shaped. An O-ring 20c serving as a sealing part is provided on an upper surface of the shutter 110 so as to be in contact with the lower end of the inlet 18. The shutter 110 is configured to close the lower end opening of the inlet 18 when the seal cap 100 is lowered to open the lower end opening of the inlet 18. The shutter 110 is configured to retract from the lower end opening of the inlet 18 when the seal cap 100 is elevated to close the lower end opening of the inlet 18. The opening/closing operation of the shutter 110 such as the elevation and the rotation is controlled by a shutter opening/closing mechanism 112 provided at the outside the reaction tube 16.

Referring to FIG. 3, a temperature sensor 114 serving as a temperature detector is provided in the reaction tube 16. The state of electricity conducted to the heater 14 is adjusted based on the temperature detected by the temperature sensor 114, such that the inner temperature of the process chamber 22 has a desired temperature distribution. Similar to the nozzles 40a and 40b, the temperature sensor 114 is provided along the inner wall of the reaction tube 16.

A controller 200 serving as a control device (control mechanism) is constituted by a computer including a CPU (Central Processing Unit) 202, a RAM (Random Access Memory) 204, a memory device 206 and an I/O port 208. The RAM 204, the memory device 206 and the I/O port 208 may exchange data with the CPU 202 through an internal bus 210. For example, an input/output device 212 such as a touch panel is connected to the controller 200.

The memory device 206 is configured by components such as a flash memory and HDD (Hard Disk Drive). An operation program of the CPU 202 is readably stored in the memory device 206. For example, a control program for controlling the operation of the substrate processing apparatus 10, a process recipe containing information on the sequences and conditions of a substrate processing (film-forming process) described later or a cleaning recipe containing information on the sequences and conditions of a cleaning process) described later is readably stored in the memory device 206.

The process recipe is obtained by combining steps of the film-forming process (substrate processing) described later such that the controller 200 can execute the steps to acquire a predetermine result, and functions as a program. The cleaning recipe is obtained by combining steps of the cleaning process described later such that the controller 200 can execute the steps to acquire a predetermine result, and functions as a program. Hereafter, the process recipe, the cleaning recipe and the control program are collectively referred to as a “program”. In the present specification, “program” may indicate only the process recipe, indicate only the cleaning recipe, indicate only the control program, or indicate any combination of the process recipe, the cleaning recipe and/or the control program.

The RAM 204 is a memory area (work area) where a program or data read by the CPU 202 is temporarily stored.

The I/O port 208 is connected to the above-described components such as the mass flow controllers (MFCs) 44a, 44c, 44d, 54a, 54b, 54c, 54d, 64a and 64b, the valves 46a, 46c, 46d, 56a, 56b, 56c, 56d, 66a and 66b, the pressure sensor 92, the APC valve 94, the vacuum pump 96, the heater 14, the temperature sensor 114, the rotating mechanism 102, the boat elevator 106 and the shutter opening/closing mechanism 112.

The CPU 202 forms a backbone of the controller 200. The CPU 202 is configured to read a control program from the memory device 206 and execute the read control program. Furthermore, the CPU 202 is configured to read a recipe such as the process recipe and the cleaning recipe from the memory device 206 according to an operation command inputted from the input/output device 212. According to the contents of the read recipe, the CPU 202 may be configured to control various operations such as flow rate adjusting operations for various gases by the MFCs 44a, 44c, 44d, 54a, 54b, 54c, 54d, 64a and 64b, opening/closing operations of the valves 46a, 46c, 46d, 56a, 56b, 56c, 56d, 66a and 66b, an opening/closing operation of the APC valve 94, a pressure adjusting operation by the APC valve 94 based on the pressure sensor 92, a temperature adjusting operation of the heater 14 based on the temperature sensor 114, a start and stop of the vacuum pump 96, an operation of adjusting rotation and rotation speed of the boat 28 by the rotating mechanism 102, an elevating and lowering operation of the boat 28 by the boat elevator 106, and an opening/closing operation of the shutter 110 by the shutter opening/closing mechanism 112.

The controller 200 may be embodied by installing the above-described program stored in an external memory device 220 into a computer. For example, the external memory device 220 may include a magnetic disk such as a hard disk, an optical disk such as a CD, a magneto-optical disk such as MO, and a semiconductor memory such as a USB memory. The memory device 206 or the external memory device 220 may be embodied by a non-transitory computer readable recording medium. Hereafter, the memory device 206 and the external memory device 220 are collectively referred to as recording media. In the present specification, the term “recording media” may indicate only the memory device 206, indicate only the external memory device 220, and indicate both of the memory device 206 and the external memory device 220. Instead of the external memory device 220, a communication means such as the Internet and a dedicated line may be used for providing the program to the computer.

Hereinafter will be described an exemplary sequence of forming a film on the substrates 24 (that is, the substrate processing or the film-forming process) and cleaning the inside of the process chamber 22 (that is, the cleaning process) after the film-forming process is completed, which is a part of a manufacturing process of a semiconductor device. The exemplary sequence is performed by using the process furnace 12 of the above-described substrate processing apparatus 10. Hereinafter, the components of the substrate processing apparatus 10 are controlled by the controller 200.

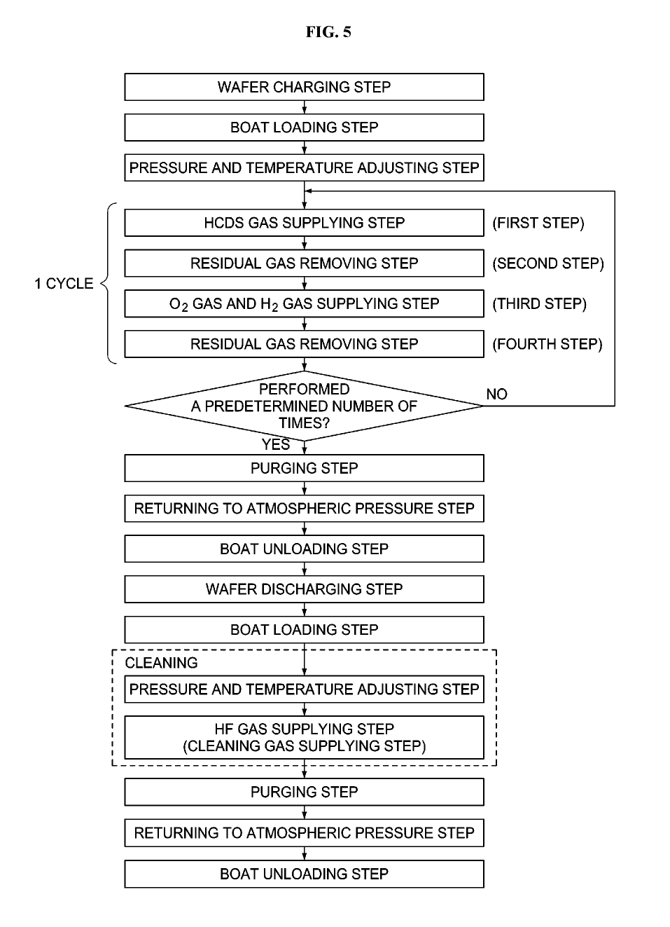

Hereinafter, an example of forming a silicon oxide film (SiO₂ film. Hereinafter, also referred to as a “SiO film”) by using the HCDS gas as the source gas and the O₂ gas and the H₂ gas as the reactive gas and cleaning the inside of the process chamber 22 by using the hydrogen fluoride (HF) gas as the cleaning gas after the SiO film is formed, will be described in detail with reference to FIGS. 5 through 8.

In the present specification, the term “wafer” may refer to “a wafer itself” or refer to “a wafer and a stacked structure (aggregated structure) of predetermined layers or films formed on the surface of the wafer”. In addition, “surface of a wafer” refers to “a surface (exposed surface) of a wafer itself” or “the surface of a predetermined layer or film formed on the wafer, i.e. the top surface of the wafer as a stacked structure”. Thus, in the present specification, “forming a predetermined layer (or film) on a wafer” may refer to “forming a predetermined layer (or film) on a surface of wafer itself” or refer to “forming a predetermined layer (or film) on a surface of a layer or a film formed on the wafer”. In the present specification, “substrate” and “wafer” may be used as substantially the same meaning. That is, the term “substrate” may be substituted by “wafer” and vice versa.

### (2) Substrate Processing (Film-Forming Process)

### Wafer Charging and Boat Loading Step

The substrates 24 are charged in the boat 28 (wafer charging step). After the boat 28 is charged with the substrates 24, the shutter 110 is moved by the shutter opening/closing mechanism 112 to open the lower end opening of the inlet 18. Then, the boat 28 charged with the substrates 24 is elevated by the boat elevator 106 and loaded into the process chamber 22 (boat loading step). With the boat 28 loaded, the seal cap 100 seals the lower end opening of the inlet 18 via the O-ring 20b.

### Pressure and Temperature Adjusting Step

The vacuum pump 96 vacuum-exhausts the process chamber 22 until the inner pressure of the process chamber 22 reaches a desired pressure (vacuum degree). In the pressure and temperature adjusting step, the inner pressure of the process chamber 22 is measured by the pressure sensor 92, and the APC valve 94 is feedback-controlled based on the measured pressure (pressure adjusting step). The vacuum pump 96 continuously vacuum-exhausts the process chamber 22 until at least the processing of the substrates 24 is completed. The heater 14 heats the process chamber 22 until the temperature of the substrates 24 in the process chamber 22 reaches a desired first temperature. The amount of the current flowing to the heater 14 is feedback-controlled based on the temperature detected by the temperature sensor 114 such that the inner temperature of the process chamber 22 has a desired temperature distribution (temperature adjusting step). The heater 14 continuously heats the process chamber 22 until at least the processing of the substrates 24 is completed. The rotating mechanism 102 rotates the boat 28. As the rotating mechanism 102 rotates the boat, the substrates 24 supported by the boat 28 are rotated. Until at least the processing of the substrates 24 is completed, the boat rotating mechanism 102 continuously rotates the boat 28 and the substrates 24.

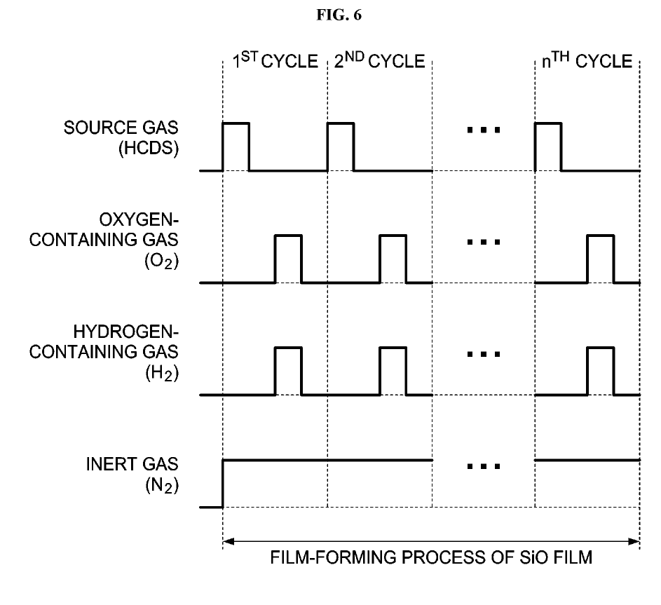

Next, the SiO film having a predetermined thickness is formed on the substrates 24 by performing a cycle including a first step, a second step, a third step and a fourth step described below a predetermined number of times as shown FIGS. 5 and 6.

### First Step

In the first step, a layer (silicon-containing layer) is formed on the substrates 24 by supplying the source gas such as the HCDS gas onto the substrates 24 accommodated in the process chamber 22.

First, the valve 46a is opened to supply the HCDS gas into the gas supply pipe 42a. The flow rate of the HCDS gas supplied into the gas supply pipe 42a is adjusted by the MFC 44a. The HCDS gas whose flow rate is adjusted is supplied onto the substrates 24 in the heated and depressurized process chamber 22 through the plurality of gas supply holes 48a of the nozzle 40a, and is exhausted through the exhaust pipe 90. As described above, the HCDS gas is supplied onto the substrates 24 (HCDS gas supplying step).

In the first step, the valve 56a may be opened to supply the inert gas such as N₂ gas through the inert gas supply pipe 52a. After the flow rate of the N₂ gas is adjusted by the MFC 54a, the N₂ gas whose flow rate is adjusted is supplied into the gas supply pipe 42a. The N₂ gas whose flow rate is adjusted is mixed with the HCDS gas whose flow rate is adjusted in the gas supply pipe 42a, then supplied onto the substrates 24 in the heated and depressurized process chamber 22 through the plurality of gas supply holes 48a of the nozzle 40a, and is exhausted through the exhaust pipe 90.

In order to prevent the HCDS gas from entering the nozzles 40b and 40c, the valves 56b, 56c and 56d are opened to supply the N2 gas into the inert gas supply pipes 52b, 52c and 52d. The N₂ gas supplied into the inert gas supply pipes 52b, 52c and 52d is then supplied into the process chamber 22 through the cleaning gas supply pipe 62b, the gas supply pipe 42c, the gas supply pipe 42d, the nozzle 40b and the nozzle 40c, and is exhausted through the exhaust pipe 90.

In the first step, the APC valve 94 is appropriately controlled to adjust the inner pressure of the process chamber 22 to a predetermined pressure. For example, the inner pressure of the process chamber 22 may range from 1 Pa to 2,000 Pa, preferably from 10 Pa to 1,330 Pa. The flow rate of the HCDS gas is adjusted to a predetermined flow rate. For example, the flow rate of the HCDS gas may range from 1 sccm to 1,000 sccm. The flow rates of the N₂ gas supplied through the gas supply pipes are adjusted to predetermined flow rates, respectively. For example, the flow rates of the N₂ gas may range from 100 sccm to 2,000 sccm, respectively. The HCDS gas is supplied onto the substrates 24 for a predetermined time. For example, the time duration of supplying the HCDS gas onto the substrates 24 may range from 1 second to 120 seconds.

In the first step, the temperature of the heater 14 is set such that the temperature of the substrates 24 is at a predetermined temperature. For example, the temperature of the substrates 24 may range from 350° C. to 800° C., preferably from 450° C. to 800° C., more preferably from 550° C. to 750° C.

By supplying the HCDS gas onto the substrates 24 under the above-described conditions, the silicon-containing layer having a thickness of, for example, less than one atomic layer to several atomic layers is formed on the substrates 24 (that is, on a underlying film or a base film of the surfaces of the substrates 24). The silicon-containing layer may be an adsorption layer of the HCDS gas, a silicon layer, or both. Preferably, the silicon-containing layer is a layer containing silicon (Si) and chlorine (Cl).

The HCDS gas supplied into the process chamber 22 is supplied not only onto the substrates 24 but also to the surfaces of the components in the process chamber 22 (for example, the inner wall of the reaction tube 16, the inner wall of the inlet 18 and the boat 28 accommodated in the process chamber 22). Therefore, the silicon-containing layer is formed not only on the substrate 24s but also on the surfaces of the components in the process chamber 22. Similar to the silicon-containing layer formed on the substrates 24, the silicon-containing layer formed on the surfaces of the components in the process chamber 22 may be the adsorption layer of the HCDS gas, the silicon layer, or both.

In the first step, instead of the HCDS gas, for example, a gas such as tetrachlorosilane gas, that is, silicon tetrachloride (SiCl₄, abbreviated as STC) gas, trichlorosilane (SiHCl₃, abbreviated as TCS) gas, dichlorosilane (SiH₂Cl₂, abbreviated as DCS) gas and monochlorosilane (SiH₃Cl, abbreviated as MCS) gas may be used as the source gas. Instead of the N₂ gas, for example, rare gases such as argon (Ar) gas, helium (He) gas, neon (Ne) gas and xenon (Xe) gas may be used as the inert gas.

### Second Step

After the silicon-containing layer is formed on the substrates 24, the valve 46a is closed to stop the supply of the HCDS gas. In the second step, with the APC valve 94 of the exhaust pipe 90 open, the vacuum pump 96 vacuum-exhausts the inside of the process chamber 22 to remove a residual gas such as the HCDS gas in the process chamber 22 from the process chamber 22 (residual gas removing step). In the second step, by maintaining the valves 56a, 56b, 56c and 56d open, the N₂ gas is continuously supplied into the process chamber 22. The N₂ gas serves as a purge gas. The flow rates of the N₂ gas supplied through the gas supply pipes are adjusted to predetermined flow rates, respectively. For example, the flow rates of the N₂ gas may range from 100 sccm to 2,000 sccm, respectively. In the second step, instead of the N₂ gas, for example, rare gases such as argon (Ar) gas, helium (He) gas, neon (Ne) gas and xenon (Xe) gas may be used as the purge gas.

### Third Step

In the third step, the O₂ gas and the H₂ gas, each of which serves as the reactive gas, is supplied onto the heated substrates 24 accommodated in the process chamber 22 under a pressure lower than the atmospheric pressure. Thereby, the layer (silicon-containing layer) formed in the first step is oxidized and modified into an oxide layer.

After the residual gas is removed, the valve 46c is opened to supply the O₂ gas into the gas supply pipe 42c. The flow rate of the O₂ gas supplied into the gas supply pipe 42c is adjusted by the MFC 44c. The O₂ gas whose flow rate is adjusted is then supplied onto the substrates 24 in the heated and depressurized process chamber 22 through the plurality of gas supply holes 48c of the nozzle 40c.

The valve 46d is opened to supply the H₂ gas into the gas supply pipe 42d. The flow rate of the H₂ gas supplied into the gas supply pipe 42d is adjusted by the MFC 44d. The H₂ gas whose flow rate is adjusted is then supplied onto the substrates 24 in the heated and depressurized process chamber 22 through the plurality of gas supply holes 48c of the nozzle 40c.

When passing through the gas supply pipe 42c, the H₂ gas is mixed with the O₂ gas in the gas supply pipe 42c. A mixed gas of the H₂ gas and the O₂ gas is then supplied onto the substrates 24 in the heated and depressurized process chamber 22 through the plurality of gas supply holes 48c of the nozzle 40c, and is exhausted through the exhaust pipe 90. As described above, the mixed gas of the H₂ gas and the O₂ gas is supplied onto the substrates 24 (O₂ gas and H₂ gas supplying step).

In the third step, the valve 56c may be opened to supply the inert gas such as the N₂ gas through the inert gas supply pipe 52c. After the flow rate of the N₂ gas is adjusted by the MFC 54c, the N₂ gas whose flow rate is adjusted is supplied into the gas supply pipe 42c. In addition, the valve 56d may be opened to supply the inert gas such as the N₂ gas through the inert gas supply pipe 52d. After the flow rate of the N₂ gas is adjusted by the MFC 54d, the N₂ gas whose flow rate is adjusted is supplied into the gas supply pipe 42c. When the N₂ gas is supplied into the gas supply pipe 42c, a mixed gas of the O₂ gas, the H₂ gas and the N₂ gas is supplied through the nozzle 40c. In the third step, instead of the N₂ gas, for example, rare gases such as argon (Ar) gas, helium (He) gas, neon (Ne) gas and xenon (Xe) gas may be used as the inert gas.

In order to prevent the O₂ gas and the H₂ gas from entering the nozzles 40a and 40b, the valves 56a and 56b are opened to supply the N₂ gas into the inert gas supply pipes 52a and 52b. The N₂ gas supplied into the inert gas supply pipes 52a and 52b is then supplied into the process chamber 22 through the gas supply pipe 42a, the nozzle 40a, the cleaning gas supply pipe 62b and the nozzle 40b, and is exhausted through the exhaust pipe 90.

In the third step, the APC valve 94 is appropriately controlled to adjust the inner pressure of the process chamber 22 to a predetermined pressure lower than the atmospheric pressure. For example, the inner pressure of the process chamber 22 may range from 1 Pa to 1,000 Pa. The flow rate of the O₂ gas is adjusted to a predetermined flow rate. For example, the flow rate of the O₂ gas may range from 1,000 sccm to 10,000 sccm. The flow rate of the H₂ gas is adjusted to a predetermined flow rate. For example, the flow rate of the H₂ gas may range from 1,000 sccm to 10,000 sccm. The flow rates of the N₂ gas supplied through the gas supply pipes are adjusted to predetermined flow rates, respectively. For example, the flow rates of the N₂ gas may range from 100 sccm to 2,000 sccm, respectively. The O₂ gas and the H₂ gas are supplied onto the substrates 24 for a predetermined time. For example, the time duration of supplying the O₂ gas and the H₂ gas onto the substrates 24 may range from 1 second to 120 seconds.

In the third step, similar to the first step, the temperature of the heater 14 is set such that the temperature of the substrates 24 is at a predetermined temperature. For example, the temperature of the substrates 24 may range from 450° C. to 800° C., preferably from 550° C. to 750° C. When the temperature of the substrates 24 is within the above-described range, it is possible to remarkably enhance the oxidation power. In addition, it is possible to further enhance the oxidation power by adding the H₂ gas to the O₂ gas under the depressurized atmosphere when the temperature of the substrates 24 is within the above-described range. When the temperature of the substrates 24 is too low, it is difficult to obtain the effect of enhancing the oxidation power.

By supplying the O₂ gas and the H₂ gas onto the substrates 24 under the above-described conditions, the O₂ gas and the H₂ gas are thermally activated (excited) in non-plasma state to undergo chemical reaction which causes to form oxidation species containing, e.g., an atomic oxygen (O) free of moisture (H₂O). Then, the silicon-containing layer formed on the substrates 24 in the first step is oxidized mainly by the above-formed oxidation species. Thereby, the silicon-containing layer is changed (modified) into a silicon oxide layer (SiO₂ layer, hereinafter, also referred to simply as a “SiO layer”) containing a small amount of impurities such as chlorine (Cl).

According to the oxidation of the silicon-containing layer as described above, it is possible to remarkably enhance the oxidation power as compared with the case where the O₂ gas is supplied alone or the water vapor (H₂O) is supplied. By adding the H₂ gas to the O₂ gas under the depressurized atmosphere, it is possible to further enhance the oxidation power as compared with the case when the O₂ gas is supplied alone or when water vapor (H₂O) is supplied.

The oxidation species generated in the process chamber 22 is not only supplied to the substrates 24 but also supplied to the surfaces of the components in the process chamber 22. As a result, similar to the silicon-containing layer formed on the substrates 24, a part of the silicon-containing layer formed on the surfaces of the components in the process chamber 22 is changed (modified) into the silicon oxide layer (SiO layer).

The oxygen-containing gas may include at least one gas selected from the group consisting of the O₂ gas and ozone (03) gas. The hydrogen-containing gas may include at least one gas selected from the group consisting of the H₂ gas and deuterium (D₂) gas.

### Fourth Step

After the silicon-containing layer is modified into the silicon oxide layer, the valve 46c is closed to stop the supply of the O₂ gas. In addition, the valve 46d is closed to stop the supply of the H₂ gas. In the fourth step, with the APC valve 94 of the exhaust pipe 90 open, the vacuum pump 96 vacuum-exhausts the inside of the process chamber 22 to remove the residual gas such as the O₂ gas and the H₂ gas in the process chamber 22 from the process chamber 22 (residual gas removing step). In the fourth step, by maintaining the valves 56a, 56b, 56c and 56d open, the N₂ gas is continuously supplied into the process chamber 22. The N₂ gas serves as the purge gas. The flow rates of the N₂ gas supplied through the gas supply pipes are adjusted to predetermined flow rates, respectively. For example, the flow rates of the N₂ gas may range from 100 sccm to 2,000 sccm, respectively. In the fourth step, instead of the N₂ gas, for example, rare gases such as argon (Ar) gas, helium (He) gas, neon (Ne) gas and xenon (Xe) gas may be used as the purge gas.

### Performing Predetermined Number of Times

By performing the cycle including the first step, the second step, the third step and the fourth step a predetermined number of times (n times), the silicon oxide film (SiO film) having a predetermined thickness is formed on the substrates 24.

### Purging and Returning to Atmospheric Pressure Step

After the silicon oxide film having the predetermined thickness is formed on the substrates 24, the N₂ gas is supplied into the process chamber 22 through the inert gas supply pipes 52a, 52b, 52c and 52d, respectively, and then the N₂ gas supplied into the process chamber 22 is exhausted through the exhaust pipe 90. The N₂ gas serves as the purge gas. The inside of the process chamber 22 is purged with the inert gas (purge gas) such as the N₂ gas, thus the residual gas in the process chamber 22 are removed from the process chamber 22 by supplying the N₂ gas (purging step). Thereafter, the inner atmosphere of the process chamber 22 is replaced with the inert gas, and the inner pressure of the process chamber 22 is returned to the atmospheric pressure (returning to atmospheric pressure step).

### Boat Unloading and Wafer Discharging Step

Thereafter, the seal cap 100 is lowered by the boat elevator 115 and the lower end of the inlet 18 is opened. The boat 24 with the processed substrates 24 charged therein is unloaded out of the reaction tube 16 through the lower end of the inlet 18 (boat unloading step). After the boat 28 is unloaded, the shutter 110 is moved by the shutter opening/closing mechanism 112. The lower end of the inlet 18 is sealed by the shutter 110 through the O-ring 20c (shutter closing step). Then, the processed substrates 24 (that is, the substrates 24 after batch processing is performed) are then discharged from the boat 28 (wafer discharging step).

### (3) Cleaning Process

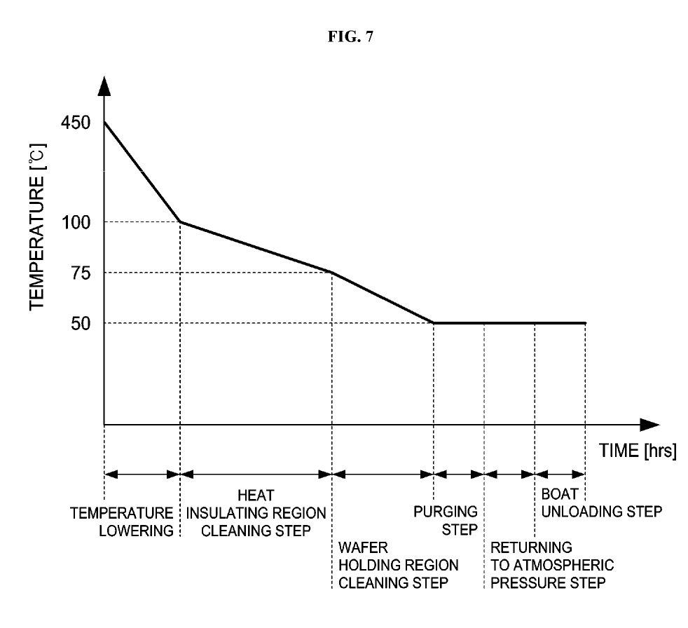

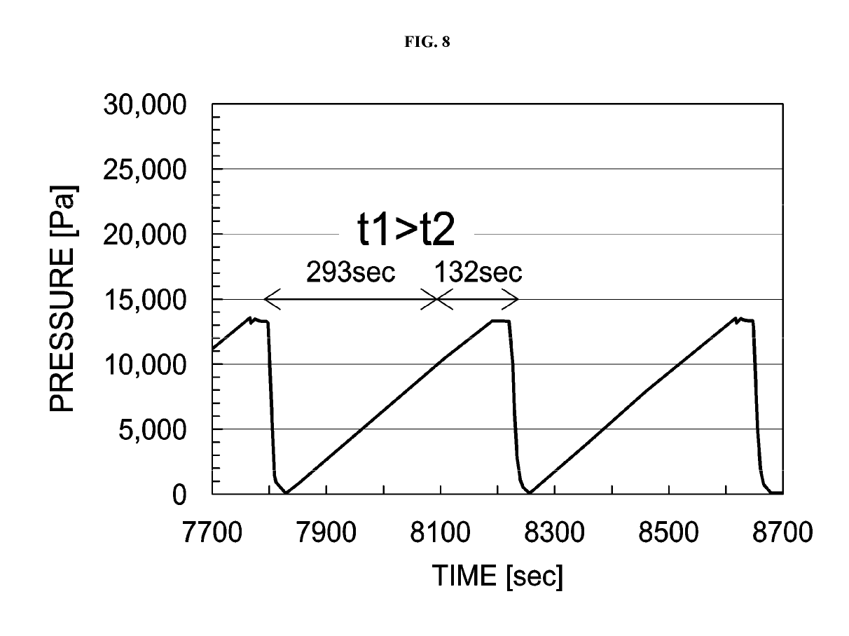

Subsequently, the cleaning process for cleaning the inside of the process chamber 22 is performed based on timing diagrams of the temperature and the pressure respectively shown in FIGS. 7 and 8.

When the SiO film is formed by the film forming process described above, the film is also deposited on the surfaces of the components in the process chamber 22 such as the inner wall of the reaction tube 16, the inner wall of the inlet 18 and the boat 28 accommodated in the process chamber 22. The deposited film is accumulated by performing (repeating) the batch processing described above, and gradually becomes thicker. The accumulated deposited film may be peeled off in subsequent substrate processing and adhere to the substrates 24. Thus, particles may be generated. Therefore, in preparation for the subsequent substrate processing, when the thickness of the accumulated deposited film reaches a predetermined thickness, the accumulated deposited film is removed from the process chamber 22. In the embodiments, an example when the predetermined thickness is 3,000 nm will be described.

### Boat Loading Step

The boat 28 without any substrate 24 charged therein (that is, an empty boat 28) is loaded into the process chamber 22 in the same manners as in the boat loading step of the film-forming process.

### Pressure and Temperature Adjusting Step

The vacuum pump 96 vacuum-exhausts the process chamber 22 until the inner pressure of the process chamber 22 reaches a desired pressure (vacuum degree). In the pressure and temperature adjusting step, the inner pressure of the process chamber 22 is measured by the pressure sensor 92, and the APC valve 94 is feedback-controlled based on the measured pressure (pressure adjusting step). The vacuum pump 96 continuously vacuum-exhausts the process chamber 22 until at least the cleaning process for cleaning the inside of the process chamber 22 is completed.

In the pressure and temperature adjusting step, the inner temperature of the process chamber 22 is stabilized at a predetermined temperature (for example, 450° C.) serving as a first temperature, as shown in FIG. 7. The amount of the current flowing to the heater 14 is feedback-controlled based on the temperature detected by the temperature sensor 114 such that the inner temperature of the process chamber 22 has a desired temperature distribution (temperature adjusting step). Thereafter, the inner temperature of the process chamber 22 is lowered from 450° C., for example. When lowering the inner temperature of the process chamber 22, the amount of the current flowing to the heater 14 may be feedback-controlled as described above to adjust the inner temperature of the process chamber 22, or the current flowing to the heater 14 may be shut off instead of being feedback-controlled. It is possible to lower the inner temperature of the process chamber 22 quickly by shutting off the power supply to the heater 14. However, the inner temperature of the process chamber 22 can be controlled (or measured) in both cases described above. When the temperature reaches a second temperature, a third temperature and fourth temperature, respectively, which will be described later, the inner temperature of the process chamber 22 is adjusted (stabilized) as described above.

Thereafter, after the inner temperature of the process chamber 22 is stabilized at the first temperature, the rotating mechanism 102 rotates the boat 28. As the rotating mechanism 102 rotates the boat 28, the substrates 24 supported by the boat 28 are rotated. Until at least the processing of the substrates 24 is completed, the boat rotating mechanism 102 continuously rotates the boat 28 and the substrates 24. However, the boat 28 may not be rotated in the cleaning process.

### Cleaning Gas Supplying Step

Thereafter, the cleaning gas is supplied into the process chamber 22 when the inner temperature of the process chamber 22 detected by the temperature sensor 114 is the second temperature lower than the first temperature and higher than the room temperature. In the cleaning gas supplying step, first, the cleaning gas is supplied into the process chamber 22 through the nozzle 40b while the inner temperature of the process chamber 22 is being lowered from the second temperature (for example, 100° C.) to the third temperature (for example, 75° C.) lower than the second temperature (heat insulating region cleaning step), and thereafter, the cleaning gas is supplied into the process chamber 22 through the nozzle 40c while the inner temperature of the process chamber 22 is being lowered from the third temperature (for example, 75° C.) to the fourth temperature (for example, 50° C.) lower than the third temperature (wafer holding region cleaning step). It is possible to complete the heat insulating region cleaning step and the wafer holding region cleaning step by supplying the cleaning gas while the inner temperature is maintained, for a predetermined period, at their final temperatures (for example, 75° C. for the heat insulating region cleaning step and 50° C. for the wafer holding region cleaning step), respectively. In addition, the second temperature is not limited to 100° C., the third temperature is not limited to 75° C., and the fourth temperature is not limited to 50° C. Hereinafter, the heat insulating region cleaning step and the wafer holding region cleaning step will be described in detail.

### Heat Insulating Region Cleaning Step

First, the valve 66b is opened to supply the cleaning gas such as the HF gas into the gas supply pipe 62b. The flow rate of the HF gas supplied into the gas supply pipe 62b is adjusted by the MFC 64b. The HF gas whose flow rate is adjusted is then supplied into the process chamber 22 through the gas supply hole 48b of the nozzle 40b, and contacts the surfaces of the components such as the inner wall of the inlet 18, the upper surface of the seal cap 100 and a side surface of the rotating shaft 104. The HF gas is then exhausted through the exhaust pipe 90. Specifically, the deposits deposited on the components constituting the heat insulating region such as the inlet 18, the heat insulating part 30 and the rotating shaft 104 are removed by reacting with the HF gas. In addition, the nozzle 40b is configured to supply the HF gas directly to the heat insulating part 30 through the gas supply hole 48b. Particularly, since the nozzle 40b is configured to supply the HF gas directly to the heat insulating part 30, it is possible to efficiently remove the deposits deposited on the heat insulating part 30. Since the HF gas supplied through the nozzle 40b is in contact with the other components in the process chamber 22 and then exhausted through the exhaust pipe 90, the deposits deposited on the components constituting the wafer holding region such as the boat 28 may be removed. In the heat insulating region cleaning step, the valves 56c and 56d are opened to supply the inert gas such as the N2 gas through the nozzle 40c.

In the heat insulating region cleaning step, preferably, in order to prevent the HF gas from entering the nozzle 40a, the valve 56a is opened to supply the N₂ gas into the inert gas supply pipe 52a. The N₂ gas supplied into the inert gas supply pipe 52a is then supplied into the process chamber 22 through the gas supply pipe 42a and the nozzle 40a, and is exhausted through the exhaust pipe 90.

In the heat insulating region cleaning step, the HF gas is supplied through the nozzle 40b. When inner temperature of the process chamber 22 is lowered to about 75° C. as the third temperature, the valves 66b, 56c and 56d are closed to stop the supply of the HF gas through the cleaning gas supply pipe 62b and to stop the supply of the N₂ gas through the inert gas supply pipes 52c and 52d.

### Wafer Holding Region Cleaning Step

Thereafter, the valve 66a is opened to supply the cleaning gas such as the HF gas into the gas supply pipe 62a. The flow rate of the HF gas supplied into the gas supply pipe 62a is adjusted by the MFC 64a. The HF gas whose flow rate is adjusted is then supplied into the process chamber 22 through the plurality of gas supply holes 48c of the nozzle 40c, and contacts the surfaces of the components such as the inner wall of the reaction tube 16, the inner wall of the inlet 18 and the surface of the boat 28. The HF gas is then exhausted through the exhaust pipe 90. Specifically, the deposits deposited on the components constituting the wafer holding region such as the reaction tube 16, the inlet 18 and the boat 28 are removed by reacting with the HF gas. Since the HF gas supplied through the plurality of gas supply holes 48c of the nozzle 40c is in contact with the other components in the process chamber 22 and then exhausted through the exhaust pipe 90, the deposits deposited on the components constituting the heat insulating region may be removed. In the wafer holding region cleaning step, the valve 56b is opened to supply the inert gas such as the N2 gas through the nozzle 40b.

In the wafer holding region cleaning step, preferably, in order to prevent the HF gas from entering the nozzle 40a, the valve 56a is opened to supply the N₂ gas into the inert gas supply pipe 52a. The N₂ gas supplied into the inert gas supply pipe 52a is then supplied into the process chamber 22 through the gas supply pipe 42a and the nozzle 40a, and is exhausted through the exhaust pipe 90.

In the wafer holding region cleaning step, the HF gas is supplied through the nozzle 40c. When inner temperature of the process chamber 22 is lowered to about 50° C. as the fourth temperature, the valves 66a and 56b are closed to stop the supply of the HF gas through the cleaning gas supply pipe 62a and to stop the supply of the N₂ gas through the inert gas supply pipe 52b.

In the cleaning gas supplying step including the heat insulating region cleaning step and the wafer holding region cleaning step, the APC valve 94 is adjusted to control (adjust) the inner pressure of the process chamber 22. The inner pressure of the process chamber 22 may be controlled to be constant at a predetermined pressure (for example, 13 kPa), or may be varied from about 0.1 kPa (first pressure) to 26 kPa (second pressure). For example, the inner pressure of the process chamber 22 may be varied such that a period (hereinafter, also referred to as a “time duration”) t1 during which the inner pressure of the process chamber 22 is lower than a predetermined high pressure (for example, 10 kPa) and a period t2 during which the inner pressure of the process chamber 22 is equal to or higher than the predetermined high pressure are repeated. Specifically, the inner pressure of the process chamber 22 may be varied such that the period t1 during which the inner pressure of the process chamber 22 is lower than the predetermined high pressure is longer than the period t2 during which the inner pressure of the process chamber 22 is equal to or higher than the predetermined high pressure. As shown in FIG. 8, for example, the period t1 during which the inner pressure of the process chamber 22 is lower than 10 kPa is about 293 seconds, and the period t2 during which the inner pressure of the process chamber 22 is equal to or higher than 10 kPa is about 132 seconds. By varying the inner pressure of the process chamber 22 as described above, it is possible to increase the time during which the HF gas remains in the process chamber 22 and improve the etching rate (that is, the thickness of the deposits removed in one cycle of the heat insulating region cleaning step or the wafer holding region cleaning step). Therefore, it is possible to shorten the time required for performing the heat insulating region cleaning step and the wafer holding region cleaning step. In addition, by setting the period t1 longer than the period t2, the flow rate of the HF gas is reduced, and the efficiency of using the HF gas is improved. The time required for performing one cycle of the heat insulating region cleaning step or the wafer holding region cleaning step is the time calculated by adding the period t1 and the period t2. That is, the time required for performing one cycle of the heat insulating region cleaning step or the wafer holding region cleaning step is calculated by adding 293 seconds and 132 seconds, which amounts to 425 seconds in the above example.

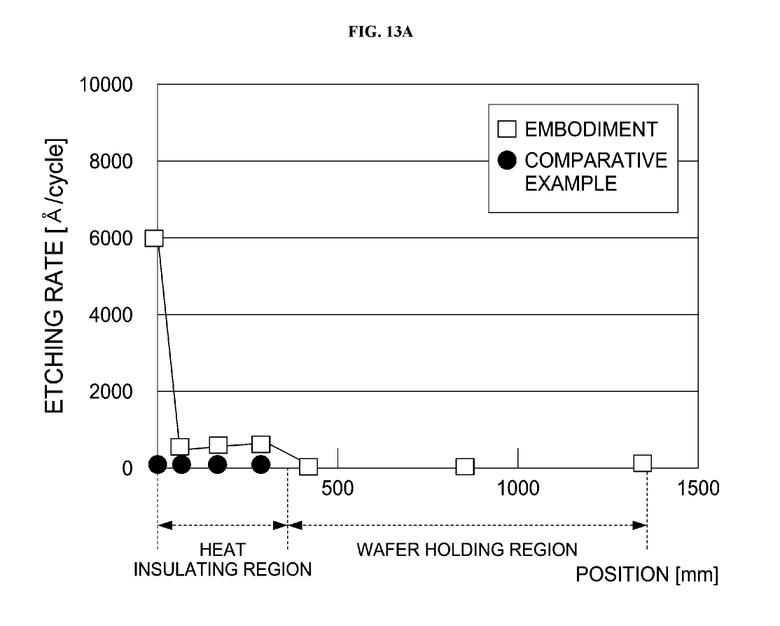

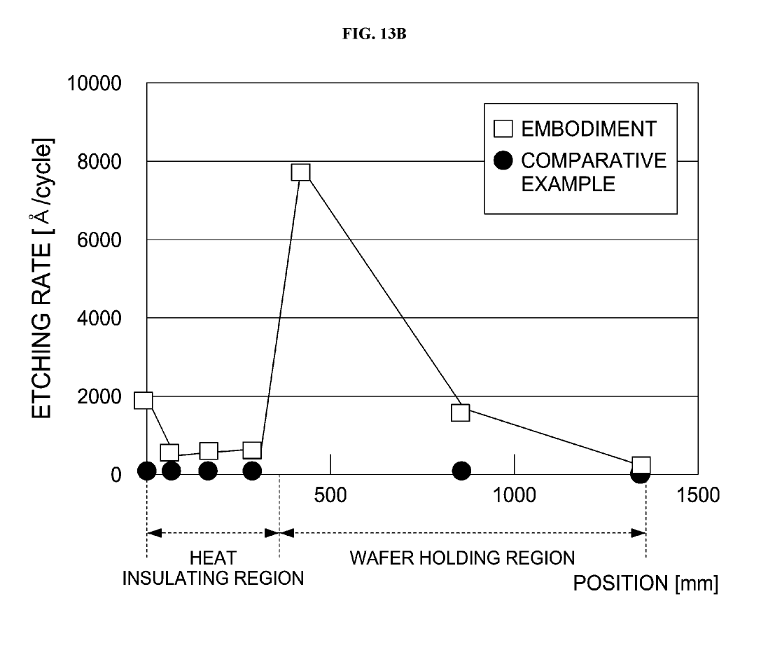

In the cleaning gas supplying step, the flow rate of the HF gas adjusted by each of the MFCs 64a and 64b is, for example, 2.0 slm. The flow rates of the N₂ gas adjusted by the MFCs 54a, 54b, 54c and 54d are, for example, 3.0 slm in total. That is, it is preferable to control the flow rates of the HF gas and the N₂ gas such that the HF gas whose flow rate is 40% of that of the N₂ gas is supplied into the process chamber 22 in the heat insulating region cleaning step and the wafer holding region cleaning step. As a result, the concentration of the HF gas in the process chamber 22 is increased. Therefore, it is possible to improve the etching rate greatly as compared with that of the comparative example described later. In addition, it is possible to improve the efficiency of using the HF gas. When the flow rates of the HF gas and the N₂ gas are controlled as described above, the etching rate is about 1900 Å/cycle as shown in FIG. 13A described later. Although the time required to perform one cycle of the heat insulating region cleaning step or the wafer holding region cleaning step may be longer than that of the comparative example described later, the number of cycles necessary for removing the deposits (deposited films) in the heat insulating region cleaning step or the wafer holding region cleaning step is greatly reduced according to the embodiments. As a result, it is possible to shorten the time required for performing the cleaning gas supplying step, thereby reducing the downtime of the apparatus.

As shown in FIG. 1, since the exhaust pipe 90 configured to exhaust the inner atmosphere of the process chamber 22 therethrough is provided closer to the heat insulating region than to the wafer holding region and the heat insulating region cleaning step is performed before the wafer holding region cleaning step, it is possible to efficiently clean the inside of the process chamber 22. In addition, instead of the HF gas alone, gases such as a gas obtained by diluting the HF gas with an inert gas such as the N₂ gas, argon (Ar) gas and helium (He) gas, a mixed gas of the HF gas and fluorine (F₂) gas and a mixed gas of the HF gas and chlorine fluoride (ClF₃) may be used as the cleaning gas.

### Purging and Returning to Atmospheric Pressure Step

After the deposits (deposited films) are removed by supplying the HF gas into the process chamber 22 when the inner temperature of the process chamber is at 50° C. which is the fourth temperature or by supplying the HF gas into the process chamber 22 for a predetermined time during which the inner temperature of the process chamber 22 is maintained at 50° C. which is the fourth temperature, the valves 56a, 56b, 56c are 56d opened to supply the inert gas such as the N₂ gas into the process chamber 22 through the inert gas supply pipes 52a, 52b, 52c and 52d, respectively. The N₂ gas supplied into the process chamber 22 is then exhausted through the exhaust pipe 90. The N₂ gas serves as the purge gas. The inside of the process chamber 22 is purged with the inert gas (purge gas) such as the N₂ gas, thus the residual gas in the process chamber 22 is removed from the process chamber 22 by supplying the N₂ gas (purging step). Thereafter, the inner atmosphere of the process chamber 22 is replaced with the inert gas, and the inner pressure of the process chamber 22 is returned to the atmospheric pressure (returning to atmospheric pressure step).

### Boat Unloading and Wafer Discharging Step

Thereafter, the boat 24 is unloaded out of the reaction tube 16 in the same manners as in the boat unloading step of the film-forming process. Thereafter, the lower end opening of the inlet 18 is sealed by the shutter 110. In addition, after the lower end opening of the inlet 18 is sealed or the boat 24 is unloaded from the reaction tube 16, the inner temperature of the process chamber 22 may be elevated to a predetermined standby temperature (for example, 450° C.).

### First Experimental Results

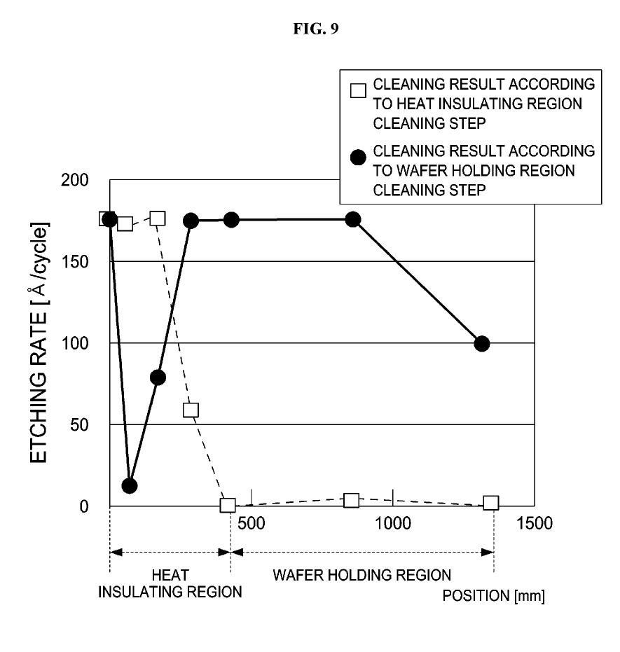

FIG. 9 schematically illustrates the etching rate obtained by performing the cleaning process according to the embodiments described above in a state where a test member is placed on the heat insulating region and the wafer holding region of the boat 28. The vertical axis of the graph shown in FIG. 9 represents the etching rate and the horizontal axis of the graph shown in FIG. 9 represents the position of the test member wherein the lower end of the boat 28 is denoted as “0”. In FIG. 9, the cleaning result according to the heat insulating region cleaning step is indicated by “□” and the cleaning result according to the wafer holding region cleaning step is indicated by “●”. In FIG. 9, the cleaning results according to the heat insulating region cleaning step and the cleaning result according to the wafer holding region cleaning step are shown together.

According to the cleaning result of the heat insulating region cleaning step shown in FIG. 9, the etching rate of the test member placed in the heat insulating region is about 175 Å/cycle, the etching rate approaches zero (0) as the test member is placed closer to the wafer holding region, and the etching rate is nearly zero (0) when the test member is placed in the wafer holding region. According to the cleaning result of the wafer holding region cleaning step shown in FIG. 9, the etching rate of the test member placed in the wafer holding region or placed at the lowermost portion of the boat 28 is about 175 Å/cycle and the etching rate of the test member placed at the uppermost portion of the boat 28 is about 100 Å/cycle, while the etching rate of the test member placed in the heat insulating region is reduced to about 10 Å/cycle.

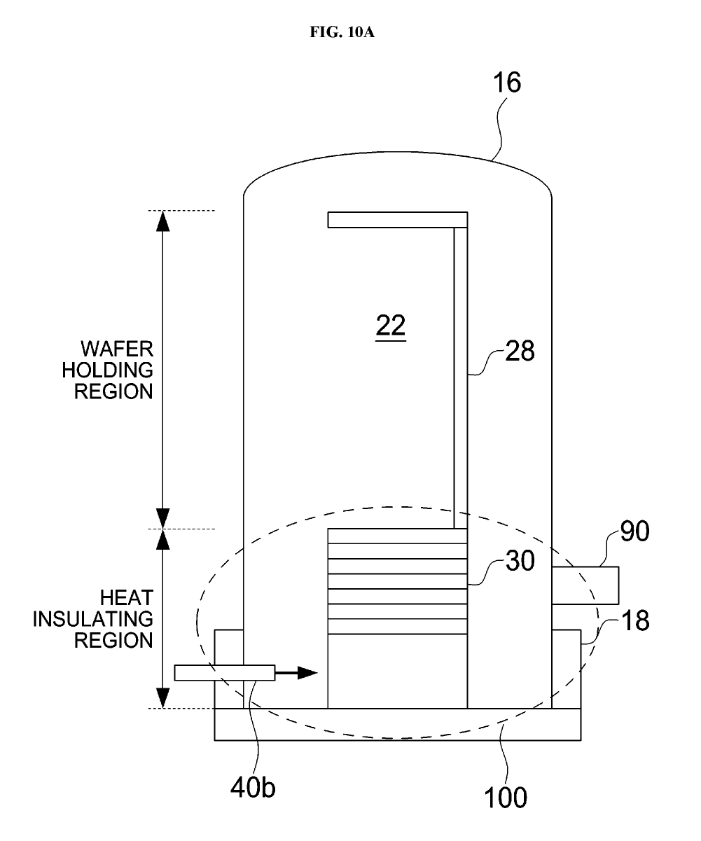

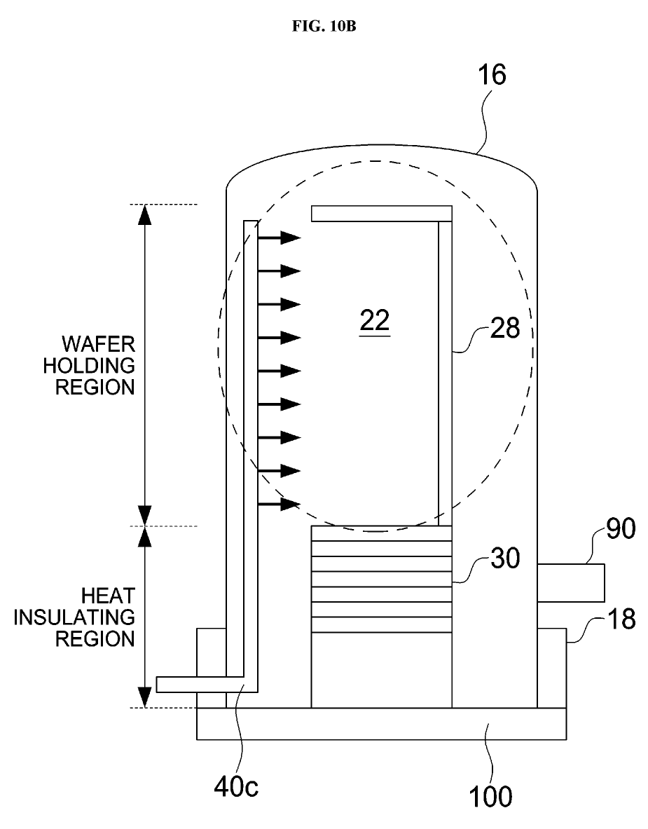

The nozzle 40b is configured to supply the gas such as the cleaning gas to the heat insulating region. Therefore, as shown in FIG. 10A, the gas as the cleaning gas easily reaches the surfaces of the components in the heat insulating region such as the inner wall of the reaction tube 16 and the inner wall of the inlet 18. Thus, when the cleaning gas is supplied through the nozzle 40b, it is likely that the portions of the components such as the reaction tube 16 in the heat insulating region is cleaned better than the portions of the components such as the reaction tube 16 in the wafer holding region. In addition, since the nozzle 40c is configured to supply the gas such as the reactive gas for reforming the silicon-containing layer formed on the substrates 24, the gas such as the reactive gas is supplied toward the vicinity of the substrates 24 accommodated in the process chamber 22 through the nozzle 40c. Therefore, as shown in FIG. 10B, when the cleaning gas is supplied through the nozzle 40c, the cleaning gas easily reaches the surfaces of the components in the wafer holding region such as the inner wall of the reaction tube 16 where the substrates 24 are accommodated. Thus, when the cleaning gas is supplied through the nozzle 40c, it is likely that the portions of the components such as the reaction tube 16 in the wafer holding region is cleaned better than the portions of the components such as the portion of the reaction tube 16 in the heat insulating region.

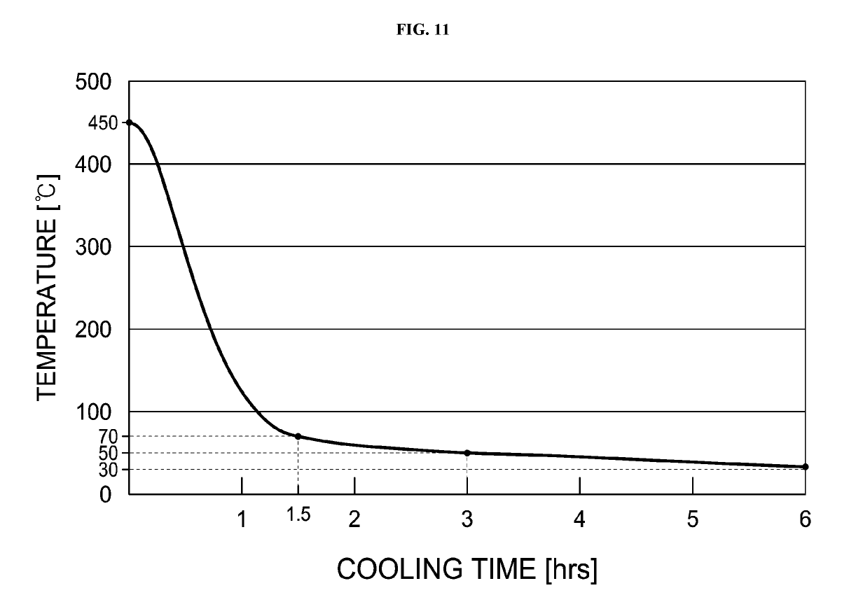

FIG. 11 schematically illustrates the relationship between the inner temperature of the process chamber 22 and the cooling time according to the embodiments. When the inner temperature of the process chamber 22 drops sharply from 450° C. to 100° C., the cooling time for reaching 100° C. is about 1.2 hours. However, when the inner temperature of the process chamber 22 further drops to a predetermined temperature lower than 100° C., the inner temperature of the process chamber 22 drops gently. Thus, the cooling time for reaching a predetermined temperature becomes longer. For example, the cooling time for lowering the inner temperature of the process chamber 22 from 450° C. to about 70° C. is about 1.5 hours, the cooling time for lowering the inner temperature of the process chamber 22 from 450° C. to about 50° C. is about 3.0 hours and the cooling time for lowering the inner temperature of the process chamber 22 from 450° C. to about 30° C. is about 6.0 hours. As described above, the cooling time for lowering the inner temperature of the process chamber 22 to the predetermined temperature becomes longer as the predetermined temperature approaches the room temperature.

However, according to the embodiments, the cleaning process is performed while changing (lowering or dropping) the inner temperature of the process chamber 22. Therefore, it is possible to shorten the time required for performing the cleaning process. According to the embodiments, first, the heat insulating region cleaning step is performed by supplying the cleaning gas to the heat insulating region through the nozzle 40b while dropping the inner temperature of the process chamber 22 from 100° C. to 75° C., wherein it is known that the heat insulating region should be cleaned at relatively high temperatures. Thereafter, the wafer holding region cleaning step is performed by supplying the cleaning gas to the wafer holding region through the nozzle 40c while dropping the inner temperature of the process chamber 22 from 75° C. to 50° C. That is, according to the embodiments, by performing the heat insulating region cleaning step and the wafer holding region cleaning step at different temperature ranges, it is possible to shorten the time required for performing the cleaning process while removing the deposits such as the reaction by-products adhered to the heat insulating region and the wafer holding region. It is also possible to suppress the variation of the etching rate depending on the location in a cleaning region such as the heat insulating region and the cleaning the wafer holding region.

### Comparative Example

Hereinafter, a cleaning process according to the comparative example of the embodiments will be described.

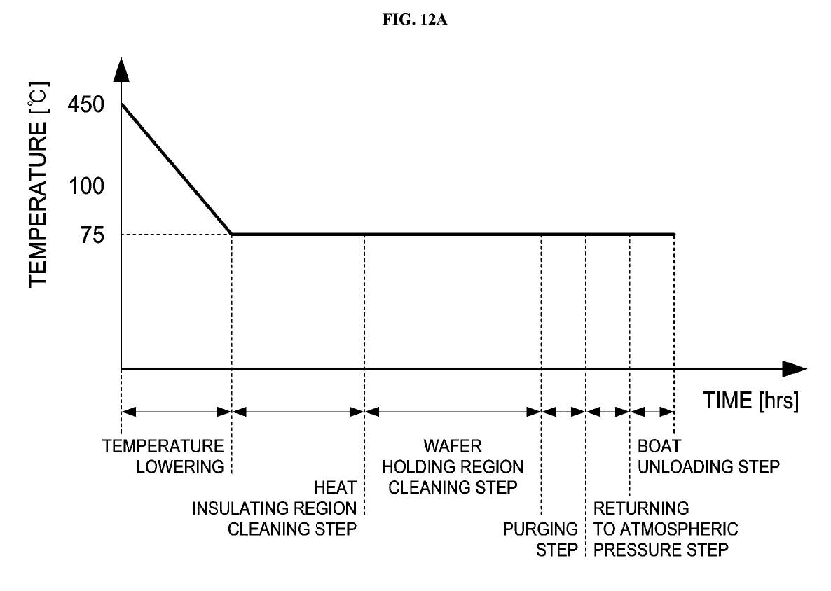

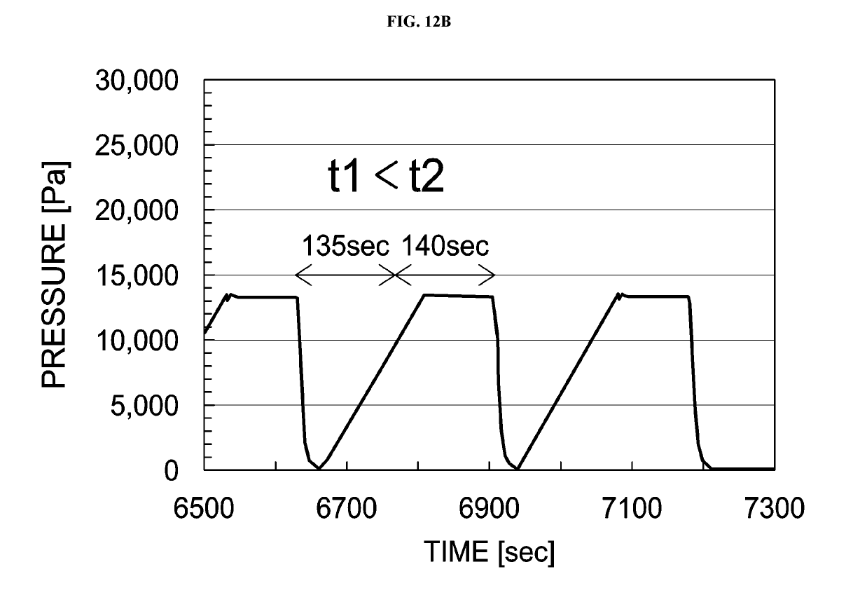

As shown in FIG. 12A, according the comparative example, after the inner temperature of the process chamber 22 is lowered from 450° C. to 75° C., operations such as a heat insulating region cleaning step, a wafer holding region cleaning step, a purging step, a returning to atmospheric pressure step and a boat unloading step, which are similar to those of the cleaning process of the embodiments, are performed while maintaining the inner temperature of the process chamber 22 at 75° C. According the comparative example, the HF gas whose flow rate is 20% of that of the nitrogen (N₂) gas is supplied into the process chamber 22. For example, the flow rate of the HF gas is 2.0 slm and the flow rates of the N₂ gas are 8.0 slm.

In a cleaning gas supplying step of the comparative example, as shown in FIG. 12B, the APC valve 94 is adjusted such that a period t1 during which the inner pressure of the process chamber 22 is lower than 10 kPa and a period t2 during which the inner pressure of the process chamber 22 is equal to or higher than 10 kPa are alternated, wherein the period t2 is longer than the period t1. For example, the period t1 during which the inner pressure of the process chamber 22 is lower than 10 kPa is about 135 seconds, and the period t2 during which the inner pressure of the process chamber 22 is equal to or higher than 10 kPa is about 140 seconds. According to the comparative example, by varying the inner pressure of the process chamber 22 such that the period t2 is longer than the period t1, the etching rate may be improved. As the period t2 becomes longer, the flow of the cleaning gas becomes continuous, thereby locally increasing the etching rate. However, the time required for performing the cleaning process may become longer as a whole. Thus, the overall cleaning performance may deteriorate. That is, according to the comparative example, the time required for performing the cleaning process is longer than that of the embodiments.

### Second Experimental Results

FIGS. 13A and 13B schematically illustrate the etching rates obtained by performing the cleaning process according to the embodiment described above and the cleaning process according to the comparative example in a state where a test member is placed on the heat insulating region and the wafer holding region of the boat 28. FIG. 13A schematically illustrates the etching rates obtained by performing the heat insulating region cleaning steps according to the embodiment and according to the comparative example, respectively. FIG. 13B schematically illustrates the etching rates obtained by performing the wafer holding region cleaning steps according to the embodiment and according to the comparative example, respectively. The vertical axes of the graphs shown in FIGS. 13A and 13B represent the etching rates and the horizontal axes of the graphs shown in FIGS. 13A and 13B represent the position of the test member wherein the lower end of the boat 28 is denoted as “0”. In FIGS. 13A and 13B, the cleaning result according to the embodiment is indicated by “□” and the cleaning result according to the comparative example is indicated by “●”.

According to the cleaning process of the embodiment, the average etching rate obtained by performing the heat insulating region cleaning step is about 1,900 Å/cycle as shown in FIG. 13A, and the average etching rate obtained by performing the wafer holding region cleaning step is about 3,100 Å/cycle as shown in FIG. 13B. According to the cleaning process of the comparative example, the average etching rate obtained by performing the heat insulating region cleaning step is about 10 Å/cycle as shown in FIG. 13A, and the average etching rate obtained by performing the wafer holding region cleaning step is about 5 Å/cycle as shown in FIG. 13B. According to the cleaning process of the embodiment, the etching rate obtained by performing the heat insulating region cleaning step is increased by about 190 times and the etching rate by performing the wafer holding region cleaning step is improved by about 620 times as compared with those of the comparative example.

According to the cleaning process of the embodiments shown in FIGS. 7 and 8, the time required for performing the heat insulating region cleaning step (that is, the time obtained by multiplying the time required for performing one cycle of the heat insulating region cleaning step by the number of the cycle of the heat insulating region cleaning step) is about 3 hours, and the time required for performing the wafer holding region cleaning step is about 2 hours. Thus, it takes about 10 hours to complete the cleaning process from the boat loading step to the boat unloading step according to the cleaning process of the embodiments. However, according to the cleaning process of the comparative example shown in FIGS. 12A and 12B, the time required for performing the heat insulating region cleaning step (that is, the time obtained by multiplying the time required for performing one cycle of the heat insulating region cleaning step by the number of the cycle of the heat insulating region cleaning step) is about 7 hours, and the time required for performing the wafer holding region cleaning step is about 10.5 hours. Thus, it takes about 24 hours to complete the cleaning process from the boat loading step to the boat unloading step according to the comparative example.

For example, when cleaning the SiO film using the HF gas, it is preferable to perform the cleaning process at about 30° C., since the etching rate improves as the temperature is as low as 100° C. or less. However, it takes a lot of time to lower the temperature to a processing temperature (or standby temperature). For example, as shown in FIG. 11, the cooling time required for lowering the temperature from 450° C. to 30° C. is about 6 hours. That is, there is trade-off relationships between the temperature suitable for performing the cleaning process using the HF gas and the cooling time (or temperature lowering time) required for lowering the inner the temperature of the process chamber 22.

However, according to the embodiments, first, the heat insulating region cleaning step is performed by supplying the cleaning gas through the nozzle 40b while lowering the inner temperature of the process chamber 22 from 100° C. to 75° C., and subsequently, the wafer holding region cleaning step is performed by supplying the cleaning gas through the nozzle 40c while lowering the inner temperature of the process chamber 22 from 75° C. to 50° C. Thereby, it is possible to shorten the time required for lowering the temperature. In addition, for example, it is possible to remove the reaction by-products in the heat insulating region and the wafer holding region more meticulously as compared with the case where the cleaning gas is supplied while maintaining the inner temperature of the process chamber 22 at a constant temperature as shown in the comparative example. Thus, it is possible to shorten the time required for cleaning the inside of the process chamber 22, and to improve the throughput.

According to the embodiments, the second temperature may not be the same as the temperature at which the heat insulating region cleaning step is started or terminated, and the third temperature may not be the same as the temperature at which the wafer holding region cleaning step is started or terminated.

According to the embodiments, one or more advantageous effects described below can be achieved.

(a) According to the embodiments, it is possible to shorten the time required for performing the cleaning process by performing the cleaning process under 100° C. and varying (lowering) the inner temperature of the process chamber 22 during the cleaning process.

(b) According to the embodiments, the cleaning process is performed by changing the region to be cleaned according to the inner temperature of the process chamber 22. Therefore, it is possible to shorten the time required for performing the cleaning process while suppressing the variation of the etching rate depending on the location in the cleaning region.

(c) According to the embodiments, the cleaning process is performed by varying the inner pressure of the process chamber. As a result, the flow velocity of the cleaning gas is decreased and the time during which the HF gas remains in the process chamber 22 is increased. Therefore, it is possible to improve the efficiency of using the HF gas and the etching rate. Since the number of cycles necessary for removing the deposits in the heat insulating region cleaning step, for example, is greatly reduced, it is also possible to shorten the time required for performing the cleaning process.

(d) According to the embodiments, the cleaning process is performed by supplying the HF gas and the N₂ gas such that the flow rate of the HF gas is lower than that of the N₂ gas. As a result, it is possible to improve the efficiency of using the HF gas and the etching rate. Since the number of cycles necessary for removing the deposits in the cleaning process is greatly reduced, it is also possible to shorten the time required for performing the cleaning process.

(e) According to the embodiments, the cleaning process is performed by considering the trade-off relationships between the temperature suitable for performing the cleaning process using the HF gas and the cooling time (or temperature lowering time) required for lowering the inner the temperature of the process chamber 22. Therefore, it is possible to shorten the time required for performing the cleaning process while suppressing the variation of the etching rate depending on the location in the cleaning region.

(f) According to the embodiments, the cleaning process may be performed by adjusting the cleaning conditions (for example, by increasing the concentration of the cleaning gas). Thus, it is possible to expand the temperature range suitable for performing the cleaning process. Since the cleaning process may be started at a temperature higher than the conventional cleaning temperature, it is possible to shorten the time required for performing the cleaning process.

(g) According to the embodiments, the cleaning process may be performed by adjusting the cleaning conditions (for example, by increasing the concentration of the cleaning gas). Therefore, it is possible to suppress the variation of the etching rate depending on the location in the cleaning region.

(h) According to the embodiments, the cleaning process may be performed by adjusting the cleaning conditions (for example, by increasing the concentration of the cleaning gas). Therefore, it is possible to set the cleaning region according to the inner the temperature of the process chamber 22. As a result, it is possible to suppress the variation of the etching rate depending on the location in the cleaning region.

### Modified Example

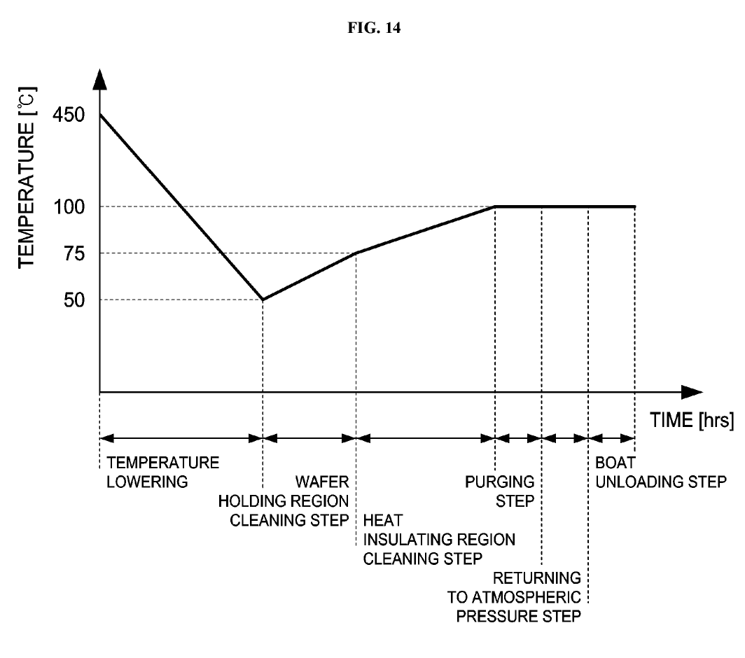

Hereinafter, a modified example of the cleaning process according to the embodiments will be described with reference to FIG. 14. In the modified example, only such portions different from the above embodiments will be described below, and the description of the portions same as the above embodiments will be omitted.

According to a cleaning process of the modified example, after the inner temperature of the process chamber 22 is lowered from 450° C. to 50° C., the wafer holding region cleaning step is performed by supplying the HF gas through the nozzle 40c while elevating the inner temperature of the process chamber 22 from 50° C. to 75° C., and the heat insulating region cleaning step is performed by supplying the HF gas through the nozzle 40b while elevating the inner temperature of the process chamber 22 from 75° C. to 100° C. After the heat insulating region cleaning step is completed, the steps such as a purging step at 100° C. as a standby temperature, the returning to atmospheric pressure step and the boat unloading step are performed.

According to the modified example, the same advantageous effects as the embodiments may be obtained.

### Other Embodiments

While the above-described embodiments are described by way of an example in which the SiO film, that is, a silicon-based film containing silicon as a semiconductor element is formed, the above-described technique is not limited thereto. For example, the above-described technique may be applied to the formations of other films such as a metal-based film containing a metal element such as titanium (Ti), zirconium (Zr), hafnium (Hf), tantalum (Ta), aluminum (Al) and molybdenum (Mo).

As described above, the above-described technique may be applied not only to the formation of the silicon-based film but also to the formations of other films such as the metal-based film. The same advantageous effects as the embodiments may be obtained when the above-described technique is applied to the formation of the metal-based film. That is, the above-described technique may be suitably applied to the formation of the film containing a predetermined element such as a semiconductor element or a metal element.

While the above-described embodiments are described based on a case in which the cleaning gas is supplied into the process chamber 22 after the boat 28 is loaded in the cleaning process (that is, the cleaning process for cleaning the inside of the process chamber 22 is performed with the boat 28 accommodated in the process chamber 22), the above-described technique is not limited thereto. For example, when the cleaning of the boat 28 is unnecessary, the boat loading step may be omitted and the cleaning gas may be supplied into the process chamber 22 without the boat 28 loaded (that is, the boat 28 is not accommodated in the process chamber 22). That is, the above-described technique may be applied to the cleaning process in which the boat loading step is omitted.

While the above-described embodiments are described based on a case in which the cleaning gas is sequentially supplied through one of the nozzle 40b and the nozzle 40c, the above-described technique is not limited thereto. For example, above-described technique may also be applied to a case where the cleaning gas is supplied simultaneously through the nozzle 40b and the nozzle 40c. Further, the above-described technique is not limited to the above-described case in which the cleaning gas supply pipe 62a is connected to the gas supply pipe 42c. For example, above-described technique may also be applied to a case where the cleaning gas supply pipe 62a is connected to the gas supply pipe 42a or to both of the gas supply pipe 42a and the gas supply pipe 42c.

The above-described technique may also be embodied by changing an existing process recipe and an existing cleaning recipe stored in a predetermined substrate processing apparatus to a new process recipe and a new cleaning recipe according to the embodiments. When changing the existing process recipe and the existing cleaning recipe to the new process recipe and the new cleaning recipe, the new process recipe and the new cleaning recipe may be installed in the predetermined substrate processing apparatus via the telecommunication line or the recording medium in which the new process recipe and the new cleaning recipe are stored. The existing process recipe and the existing cleaning recipe may be changed to the new process recipe and the new cleaning recipe by operating the input/output device of the predetermined substrate processing apparatus.

The above-described technique is not limited to the semiconductor manufacturing apparatus, but may also be applied to, e.g., an apparatus for processing a glass substrate such as an LCD manufacturing apparatus. While the above-described embodiments are described based on a case in which the cleaning process is performed after the film is deposited on the substrates, the above-described technique is not limited thereto. For example, the above-described technique may also be applied to the processes such as an oxidation process, a diffusion process and an annealing process. The above-described embodiments and modified examples may be appropriately combined. The processing conditions of the combinations may be substantially the same as the above-described embodiments or the modified examples.

The above-described technique may be applied to the cleaning process of the substrate processing apparatus capable of processing the substrates, particularly to the cleaning process capable of shortening the time required for performing the cleaning process.

According to the technique described herein, it is possible to suppress the variation of the etching rate depending on the location in the cleaning region and to shorten the time required for performing the cleaning process.

What is claimed is:

1. A processing method comprising:
(a) processing a substrate accommodated in a substrate holding region of a substrate retainer in a process chamber at a first temperature, the substrate retainer comprising a heat insulating region on one end thereof and the substrate holding region on the other end thereof;
(b) supplying a cleaning gas to the heat insulating region at a second temperature variable within a temperature range lower than the first temperature and higher than a room temperature after unloading the substrate accommodated in the substrate retainer; and
(c) supplying the cleaning gas to the substrate holding region at a third temperature variable within another temperature range lower than the second temperature after unloading the substrate accommodated in the substrate retainer.

2. The processing method of claim 1, wherein the second temperature at a timing of starting (b) differs from the second temperature at a timing of terminating (b).

3. The processing method of claim 1, wherein the third temperature at a timing of starting (c) differs from the third temperature at a timing of terminating (c).

4. The processing method of claim 2, wherein the second temperature at the timing of terminating (b) is lower than the second temperature at the timing of starting (b).

5. The processing method of claim 3, wherein the third temperature at the timing of terminating (c) is lower than the third temperature at the timing of starting (c).

6. The processing method of claim 2, wherein the second temperature at the timing of terminating (b) is higher than the second temperature at the timing of starting (b).

7. The processing method of claim 3, wherein the third temperature at the timing of terminating (c) is higher than the second temperature at the timing of starting (c).

8. The processing method of claim 1, wherein an inner temperature of the process chamber is elevated to a standby temperature after (b) and (c) are completed.

9. The processing method of claim 1, wherein an inner pressure of the process chamber is varied within a range from a first pressure to a second pressure.

10. The processing method of claim 1, wherein an inner pressure of the process chamber is varied such that a first period during which the inner pressure of the process chamber is lower than 10 kPa and a second period during which the inner pressure of the process chamber is equal to or higher than 10 kPa are alternated, the first period being longer than the second period.

11. The processing method of claim 1, wherein the cleaning gas comprises a fluorine-containing gas.

12. The processing method of claim 11, wherein the fluorine-containing gas comprises a HF gas.

13. The processing method of claim 1, wherein an exhaust pipe is provided closer to the heat insulating region than to the substrate holding region, wherein an inner atmosphere of the process chamber is exhausted through the exhaust pipe.

14. A method of manufacturing a semiconductor device, comprising:
(a) processing a substrate accommodated in a substrate holding region of a substrate retainer in a process chamber at a first temperature, the substrate retainer comprising a heat insulating region on one end thereof and the substrate holding region on the other end thereof;
(b) supplying a cleaning gas to the heat insulating region at a second temperature variable within a temperature range lower than the first temperature and higher than a room temperature after unloading the substrate accommodated in the substrate retainer; and
(c) supplying the cleaning gas to the substrate holding region at a third temperature variable within another temperature range lower than the second temperature after unloading the substrate accommodated in the substrate retainer.

15. A non-transitory computer-readable recording medium storing a program used for a substrate processing apparatus comprising a process chamber wherein a substrate is processed while the substrate is accommodated in a substrate holding region of a substrate retainer comprising a heat insulating region on one end thereof and the substrate holding region on the other end thereof; a heating system configured to heat the process chamber; a cleaning gas supply system configured to supply a cleaning gas into the process chamber; and a controller configured to control the heating system and the cleaning gas supply system to process the substrate accommodated in the substrate holding region at a first temperature and to supply the cleaning gas into the process chamber after the substrate is unloaded from the process chamber, wherein the program causes the controller to perform:
(a) supplying the cleaning gas to the heat insulating region at a second temperature variable within a temperature range lower than the first temperature and higher than a room temperature; and
(b) supplying the cleaning gas to the substrate holding region at a third temperature variable within a temperature range lower than the second temperature after unloading the substrate accommodated in the substrate retainer.
